(19) United States
(12) Patent Application Publication
(10) Pub. No.: US 2026/0198286 A1
(43) Pub. Date: Jul. 9, 2026

(54) SEMICONDUCTOR DEVICE AND METHOD FOR MANUFACTURING SEMICONDUCTOR DEVICE

(71) Applicant: RAPIDUS CORPORATION, Tokyo (JP)

(72) Inventor: Tatsuya Usami, Albany, NY (US)

(21) Appl. No.: 19/557,967

(22) Filed: Mar. 5, 2026

Related U.S. Application Data
(63) Continuation of application No. PCT/JP2024/023204, filed on Jun. 26, 2024.
(60) Provisional application No. 63/539,249, filed on Sep. 19, 2023.

(51) Int. Cl. H10W 20/42; H10W 20/00; H10W 20/41; H10W 20/45; H10W 20/46

(52) U.S. Cl. CPC H10W 20/422; H10W 20/0633; H10W 20/0698; H10W 20/425; H10W 20/435; H10W 20/455; H10W 20/46

(57) ABSTRACT

In one example, a semiconductor device includes lower conductive patterns formed above a substrate, a first insulating film formed above the substrate and filling gaps between respective lower conductive patterns, upper conductive patterns formed on the first insulating film and joined to the lower conductive patterns, and a second insulating film formed on the first insulating film and filling gaps between respective upper conductive patterns. A recess having an upper end surface of the lower conductive pattern as a bottom surface is formed from an upper surface of the first insulating film, in a portion where the lower conductive pattern and the upper conductive pattern are positionally deviated. The upper conductive pattern has a joint portion located lower than the upper surface of the first insulating film in the recess, and is joined so as to cover the entire upper end surface of the lower conductive pattern.

### CROSS REFERENCE TO RELATED APPLICATIONS

This application is a continuation of International Application No. PCT/JP2024/023204, filed on June 26, 2024, which claims the benefit of U.S. Provisional Application No. 63/539,249 filed September 19, 2023. The entire contents of each of these applications are incorporated herein by reference.

### TECHNICAL FIELD

The present invention relates to a semiconductor device and a method for manufacturing the semiconductor device.

### Background Art

As a technique related to a semiconductor device and a method for manufacturing the semiconductor device, Patent Literature 1 below describes the following manufacturing method. First, a plurality of conductive vias embedded in a first dielectric layer is selectively etched to form recesses on the conductive vias in the first dielectric layer. Next, a second dielectric layer is formed on upper surfaces of the first dielectric layer and the conductive vias via an etching stop layer. Next, trenches connected to the respective conductive vias are formed in the second dielectric layer and the etching stop layer, and a conductive layer is filled into the trenches and recesses on the conductive vias. As a result, as compared with a configuration in which the entire region of an upper surface of the conductive vias is formed on the same plane as a surface of the first dielectric layer, a distance between an arbitrary conductive via and a conductive layer formed in a trench on a conductive via adjacent to the arbitrary conductive via is increased (see FIG. 7 of Patent Literature 1).

### Citation List

### Patent Literature

Patent Literature 1: US 10,727,124 B2

### SUMMARY OF INVENTION

### Technical Problem

In the technique of Patent Literature 1 described above, when misalignment occurs in a trench formed in a second conductive layer with respect to a lower conductive via, a distance between a conductive via and a conductive layer on a conductive via adjacent thereto can be increased. Therefore, a breakdown voltage between adjacent conductive patterns is ensured. However, due to the occurrence of the misalignment, a contact area between the conductive via and the conductive layer filled in the trench is narrowed by the etching stop layer. This causes a problem that connection resistance between upper and lower conductive patterns increases.

Therefore, an object of the present invention is to provide a semiconductor device and a method for manufacturing the semiconductor device, capable of suppressing an increase in connection resistance between upper and lower conductive patterns while suppressing a decrease in breakdown voltage between adjacent conductive patterns due to occurrence of misalignment.

### Solution to Problem

The present invention for achieving such an object is a semiconductor device including: a plurality of lower conductive patterns formed above a substrate; a first insulating film formed above the substrate and filling gaps between the plurality of lower conductive patterns; a plurality of upper conductive patterns formed on the first insulating film and joined to the plurality of lower conductive patterns; and a second insulating film formed on the first insulating film and filling gaps between the plurality of upper conductive patterns, in which a recess having an upper end surface of the lower conductive pattern as a bottom surface is formed from an upper surface of the first insulating film, in a portion where the lower conductive pattern and the upper conductive pattern are positionally deviated, the upper conductive pattern has a joint portion located lower than the upper surface of the first insulating film in the recess, and the upper conductive pattern is joined to the lower conductive pattern so as to cover the entire upper end surface of the lower conductive pattern.

### Advantageous Effects of Invention

The present invention can provide a semiconductor device and a method for manufacturing the semiconductor device, capable of suppressing an increase in connection resistance between upper and lower conductive patterns while suppressing a decrease in breakdown voltage between adjacent conductive patterns due to occurrence of misalignment.

### BRIEF DESCRIPTION OF DRAWINGS

FIG. 1 is a cross-sectional view of a main portion of a semiconductor device of a first embodiment.

FIG. 2 is an enlarged view of a portion A in FIG. 1.

FIG. 3 is a process diagram (part 1) illustrating a method for manufacturing the semiconductor device of the first embodiment.

FIG. 4 is a process diagram (part 2) illustrating the method for manufacturing the semiconductor device of the first embodiment.

FIG. 5 is a process diagram (part 3) illustrating the method for manufacturing the semiconductor device of the first embodiment.

FIG. 6 is a process diagram (part 4) illustrating the method for manufacturing the semiconductor device of the first embodiment.

FIG. 7 is a process diagram (part 5) illustrating the method for manufacturing the semiconductor device of the first embodiment.

FIG. 8 is a process diagram (part 6) illustrating the method for manufacturing the semiconductor device of the first embodiment.

FIG. 9 is a process diagram (part 7) illustrating the method for manufacturing the semiconductor device of the first embodiment.

FIG. 10 is a process diagram (part 8) illustrating the method of manufacturing the semiconductor device of the first embodiment.

FIG. 11 is a process diagram (part 9) illustrating the method of manufacturing the semiconductor device of the first embodiment.

FIG. 12 is a process diagram (part 10) illustrating the method of manufacturing the semiconductor device of the first embodiment.

FIG. 13 is a process diagram (part 11) illustrating the method of manufacturing the semiconductor device of the first embodiment.

FIG. 14 is a process diagram (part 12) illustrating the method of manufacturing the semiconductor device of the first embodiment.

FIG. 15 is a process diagram (part 13) illustrating the method of manufacturing the semiconductor device of the first embodiment.

FIG. 16 is a process diagram (part 14) illustrating the method of manufacturing the semiconductor device of the first embodiment.

FIG. 17 is a process diagram (part 15) illustrating the method of manufacturing the semiconductor device of the first embodiment.

FIG. 18 is a cross-sectional view of another portion of the semiconductor device of the first embodiment.

FIG. 19 is a cross-sectional view of a main portion of a semiconductor device of a second embodiment.

FIG. 20 is a cross-sectional view of another portion of the semiconductor device of the second embodiment.

FIG. 21 is a cross-sectional view of a main portion of a semiconductor device of a third embodiment.

FIG. 22 is a cross-sectional view of another portion of the semiconductor device of the third embodiment.

FIG. 23 is a cross-sectional view of a main portion of a semiconductor device of a fourth embodiment.

FIG. 24 is a cross-sectional view of another portion of the semiconductor device of the fourth embodiment.

FIG. 25 is a process diagram (part 1) illustrating a method for manufacturing the semiconductor device of the fourth embodiment.

FIG. 26 is a process diagram (part 2) illustrating the method for manufacturing the semiconductor device of the fourth embodiment.

FIG. 27 is a cross-sectional view of a main portion of a semiconductor device of a fifth embodiment.

FIG. 28 is a cross-sectional view of another portion of the semiconductor device of the fifth embodiment.

FIG. 29 is a cross-sectional view of a main portion of a semiconductor device of a sixth embodiment.

FIG. 30 is a cross-sectional view of another portion of the semiconductor device of the sixth embodiment.

FIG. 31 is a process diagram (part 1) illustrating features of a method for manufacturing the semiconductor device of the sixth embodiment.

FIG. 32 is a process diagram (part 2) illustrating the features of the method for manufacturing the semiconductor device of the sixth embodiment.

FIG. 33 is a cross-sectional view of a main portion of a semiconductor device of a seventh embodiment.

FIG. 34 is a process diagram (part 1) illustrating features of a method for manufacturing the semiconductor device of the seventh embodiment.

FIG. 35 is a process diagram (part 2) illustrating the features of the method for manufacturing the semiconductor device of the seventh embodiment.

FIG. 36 is a process diagram (part 3) illustrating the features of the method for manufacturing the semiconductor device of the seventh embodiment.

FIG. 37 is a cross-sectional view of a main portion of a semiconductor device of an eighth embodiment.

FIG. 38 is a cross-sectional view of a main portion of a semiconductor device of a ninth embodiment.

FIG. 39 is a cross-sectional view of another portion of the semiconductor device of the ninth embodiment.

FIG. 40 is a cross-sectional view of the main portion of the semiconductor device of the ninth embodiment in a y direction.

FIG. 41 is a plan view of the main portion of the semiconductor device of the ninth embodiment.

FIG. 42 is a process diagram (part 1) illustrating a method for manufacturing the semiconductor device of the ninth embodiment.

FIG. 43 is a process diagram (part 2) illustrating the method for manufacturing the semiconductor device of the ninth embodiment.

FIG. 44 is a process diagram (part 3) illustrating the method for manufacturing the semiconductor device of the ninth embodiment.

FIG. 45 is a process diagram (part 4) illustrating the method for manufacturing the semiconductor device of the ninth embodiment.

FIG. 46 is a process diagram (part 5) illustrating the method for manufacturing the semiconductor device of the ninth embodiment.

FIG. 47 is a cross-sectional view of a main portion of a semiconductor device of a tenth embodiment.

FIG. 48 is a cross-sectional view of another portion of the semiconductor device of the tenth embodiment.

FIG. 49 is a cross-sectional view of the main portion of the semiconductor device of the tenth embodiment in a y direction.

FIG. 50 is a process diagram (part 1) illustrating a method for manufacturing the semiconductor device of the tenth embodiment.

FIG. 51 is a process diagram (part 2) illustrating the method for manufacturing the semiconductor device of the tenth embodiment.

FIG. 52 is a process diagram (part 3) illustrating the method for manufacturing the semiconductor device of the tenth embodiment.

FIG. 53 is a process diagram (part 4) illustrating the method for manufacturing the semiconductor device of the tenth embodiment.

FIG. 54 is a process diagram (part 5) illustrating the method for manufacturing the semiconductor device of the tenth embodiment.

### DESCRIPTION OF EMBODIMENTS

Hereinafter, embodiments of a semiconductor device of the present invention and a method for manufacturing the semiconductor device will be described in detail with reference to the drawings. The semiconductor device and the method for manufacturing the semiconductor device described in each of the embodiments are effectively applied to a semiconductor device having a wire pitch of 20 nm or less, but are not limited thereto. Note that components common to the embodiments are denoted by the same reference numerals, and redundant description will be omitted.

### First Embodiment

### Configuration of semiconductor device 1 of first embodiment

FIG. 1 is a cross-sectional view of a main portion of a semiconductor device 1 of a first embodiment. The semiconductor device 1 illustrated in FIG. 1 includes a semiconductor substrate 100 and a semiconductor element 100a formed on one main surface side of the semiconductor substrate 100. The semiconductor element 100a is, for example, a transistor including a gate electrode 101 and a source drain diffusion layer 102, and is formed in each region separated by an element isolation 103 formed in a surface layer of the semiconductor substrate 100. In addition, above the semiconductor substrate 100, a plug 201 connected to the semiconductor element 100a and a lower insulating film 300 having the plug 201 embedded therein and formed on the entire surface of the semiconductor substrate 100 are formed. Note that, here, an example of a normal transistor has been described as the semiconductor element 100a, but structures such as FinFET, GAA, and CFET may be used.

In addition, above the lower insulating film 300, a first wire M1 connected to the plug 201, a first via V1 above the first wire M1, and a first insulating film 500 having the first wire M1 and the first via V1 embedded therein are formed. The first wire M1 and the first via V1 constitute a lower conductive pattern. Above the first insulating film 500, a second wire M2 connected to the first via V1, a second via V2 above the second wire M2, and a second insulating film 700 having the second wire M2 and the second via V2 embedded therein are formed. The second wire M2 and the second via V2 constitute an upper conductive pattern.

Here, the semiconductor device 1 has a wire pitch of 20 nm or less. In this case, for the purpose of suppressing wire resistance, the first wire M1 and the first via V1, and the second wire M2 and the second via V2 are made of a post-Cu material having an electron mean free path smaller than that of copper (Cu). Examples of such a material include metal materials such as ruthenium (Ru), cobalt (Co), molybdenum (Mo), tungsten (W), rhodium (Rh), and iridium (Ir). In addition, a barrier metal or a seed barrier is not disposed on sidewalls of the first wire M1 and the first via V1 or sidewalls of the second wire M2 and the second via V2.

In addition, the first wire M1 and the first via V1 are integrally formed by patterning the same conductive layer, and form a via-attached wiring structure in which the first via V1 is integrally formed on the first wire M1. Furthermore, the first insulating film 500 having the first wire M1 and the first via V1 embedded therein is made of the same layer. Similarly, the second wire M2 and the second via V2 also form a via-attached wiring structure integrally formed by patterning the same conductive layer, and the second insulating film 700 having the second wire M2 and the second via V2 embedded therein is made of the same layer. Note that the first wire M1 and the first via V1 do not have to be made of the same post-Cu material as that of the second wire M2 and the second via V2. However, the configuration using the same post-Cu material is preferable because connection resistance between the first via V1 and the second wire M2 can be reduced.

In the above configuration, a connection structure between the first via V1 and the second wire M2 is as follows.

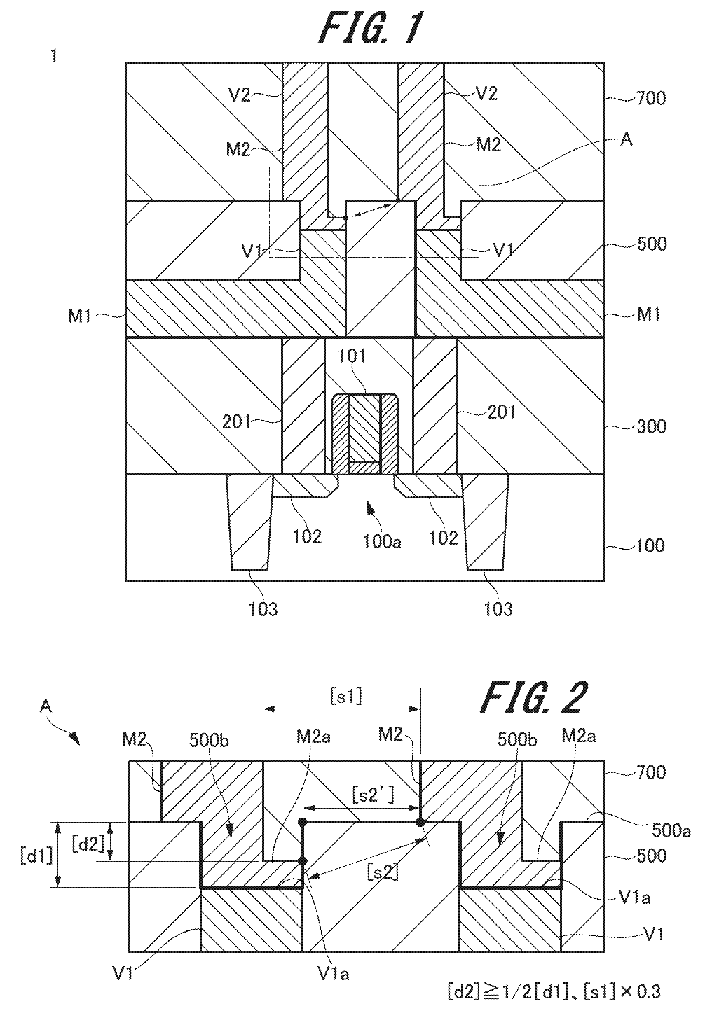

FIG. 2 is an enlarged view of a portion A in FIG. 1. As illustrated in FIG. 2, an upper end surface V1a of the first via V1 is located lower than an upper surface 500a of the first insulating film 500. As a result, a recess 500b having the upper end surface V1a of the first via V1 as a bottom surface is formed in the first insulating film 500. The second wire M2 is connected to the first via V1 in the entire bottom surface of the recess 500b, and is joined to the first via V1 so as to cover the entire upper end surface V1a of the first via V1. As a result, a connection area between the first via V1 and the second wire M2 is ensured, and an increase in connection resistance can be suppressed.

Here, the second wire M2 is formed so as to be aligned with the first via V1, but the drawing illustrates a state in which positional deviation (misalignment) occurs. If there is no positional deviation, the recess 500b is completely filled with the second wire M2. However, in a semiconductor manufacturing process with a wire pitch of 20 nm, an allowable value of alignment is 15%. Therefore, in a case of a process with a wire pitch of 20 nm and a line-and-space (L/S) of 10 nm/10 nm, positional deviation of less than 1.5 nm is allowed. Therefore, as illustrated in FIGS. 1 and 2, in the semiconductor device 1, positional deviation may occur in the second wire M2 with respect to the first via V1.

In the semiconductor device 1, as described above, the second wire M2 has a configuration in which the first via V1 is formed in the entire bottom surface of the recess 500b, and the second wire M2 and the first via V1 are connected to each other in the entire bottom surface of the recess 500b even at such a positionally deviated position. In addition, the second wire M2 has a joint portion M2a located lower than the upper surface 500a of the first insulating film 500 in the recess 500b.

A depth [d1] of the recess 500b having the upper end surface V1a of the first via V1 as a bottom surface is preferably 1/3 or more of a minimum wire interval [s1]. This facilitates a configuration having a step [d2] as described below. The minimum wire interval [s1] is a minimum interval of a conductive pattern between adjacent second wires M2.

In addition, the step [d2] from the upper surface 500a of the first insulating film 500 to the joint portion M2a of the second wire M2 is preferably 1/2 or more of the depth [d1] of the recess 500b and 30% or more of the minimum wire interval [s1] (for example, 10 nm). As a result, a substantial shortest distance [s2] between the first via V1 and the second wire M2 is ensured to be 85% or more of the minimum wire interval [s1], and a breakdown voltage (time dependent dielectric breakdown (TDDB)) between the first via V1 and the second wire M2 and a breakdown voltage (TDDB) between the second wires M2 can be ensured. In addition, the substantial shortest distance [s2] between the first via V1 and the second wire M2 is one of concerns about a decrease in breakdown voltage in a case where there is an interface between interlayer insulating films. However, the shortest distance [s2] does not pass through an interface between the first insulating film 500 and the second insulating film 700 but passes through the first insulating film 500. This also makes it possible to ensure the breakdown voltage.

Note that the substantial shortest distance [s2] between the first via V1 and the second wire M2 is a distance between an arbitrary second wire M2 and a portion of a second wire M2 portion adjacent in a deviated direction of the second wire M2 and located above the first via V1.

In addition, above the upper end surface V1a of the first via V1 in the recess 500b, the second wire M2 is preferably formed with a film thickness of at least 1 nm or more, and the film thickness is more preferably 2 nm or more. As a result, stable and appropriate connection resistance between the first via V and the second wire M2 can be obtained.

Note that, if the depth [d1] of the recess 500b can be increased within a range of 50% to 150% of the minimum wire interval [s1], the step [d2] can be increased to 40% or more, and further ensuring of the breakdown voltage can be expected. In addition, the film thickness of the second wire M2 remaining in the recess 500b can be easily controlled, and more stable and appropriate connection resistance can be obtained. In addition, the recess 500b as described above desirably has a slightly forward tapered sidewall. This improves metal embedding characteristics in a manufacturing process. In addition, when misalignment occurs in a metal etching step for forming the second wire M2, there is an effect that a metal residue is hardly generated on a sidewall of the first insulating film 500 in a metal etching region in the recess 500b.

### Method for manufacturing semiconductor device of first embodiment

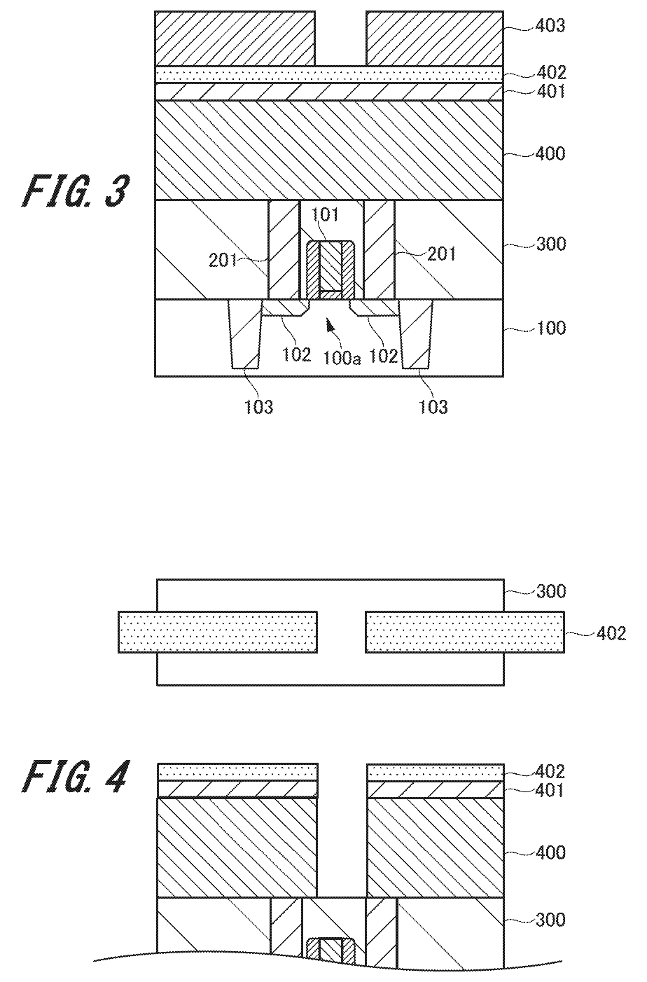

FIGS. 3 to 17 are process diagrams (part 1) to (part 15) illustrating a method for manufacturing the semiconductor device of the first embodiment. Some of FIGS. 3 to 17 illustrate cross-sectional views, and some others illustrate cross-sectional views and plan views. Hereinafter, the method for manufacturing the semiconductor device of the first embodiment will be described with reference to these drawings.

First, as illustrated in FIG. 3, the semiconductor element 100a is formed on one main surface side of the semiconductor substrate 100, and then the plug 201 connected to the semiconductor element 100a and the lower insulating film 300 in a state of filling a space between the plugs 201 are formed. At this time, an upper surface of the lower insulating film 300 and an upper surface of the plug 201 are at the same height. Thereafter, above the lower insulating film 300 and the plug 201, a first conductive film 400, a conductive hard mask layer 401, and an insulating hard mask layer 402 are formed in this order. The first conductive film 400 is formed to have a film thickness of about 40 nm using any one of the above-described metal materials other than copper, such as ruthenium. The conductive hard mask layer 401 is a layer formed as a sacrificial layer, and for example, a film of titanium nitride (TiN) is formed to have a film thickness of 5 nm. As the insulating hard mask layer 402, for example, a film of silicon nitride (SiN) is formed to have a film thickness of 5 to 10 nm. Thereafter, a resist pattern 403 is formed on the insulating hard mask layer 402. The resist pattern 403 has, for example, a wire shape in which a minimum line and space (L/S) is 10 nm/10 nm. Note that, here, multi-patterning can also be applied, and the same applies to the following patterning.

Next, as illustrated in FIG. 4, using the resist pattern 403 (see FIG. 3) as a mask, the insulating hard mask layer 402, the conductive hard mask layer 401, and the first conductive film 400 are anisotropically dry-etched in this order, and the first conductive film 400 is patterned into the shape of the first wire. Thereafter, the resist pattern 403 is stripped.

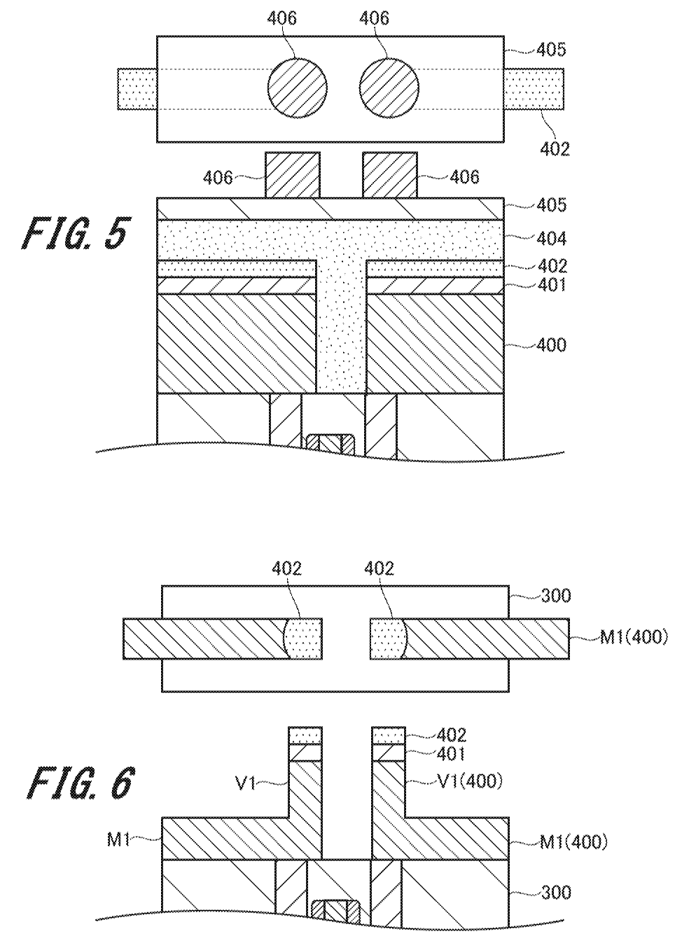

Next, as illustrated in FIG. 5, a lower resist film 404 is formed so as to have the patterned first conductive film 400, conductive hard mask layer 401, and insulating hard mask layer 402 embedded therein. Above the lower resist film 404, a low temperature oxide (LTO) film 405 and an antireflection film (not illustrated and not described below) are formed in this order. Thereafter, a via pattern mask 406 made of a resist material is formed by a lithography technique. The via pattern mask 406 is formed to be larger than a line width of the first wire (patterned first conductive film 400).

Next, using the via pattern mask 406 as a mask, the LTO film 405, the lower resist film 404, the insulating hard mask layer 402, and the conductive hard mask layer 401 are anisotropically dry-etched in this order. Subsequently, the remaining via pattern mask 406, LTO film 405, and lower resist film 404 are stripped. Thereafter, as illustrated in FIG. 6, using the insulating hard mask layer 402 as a mask, the conductive hard mask layer 401 and a portion located 20 nm above the first conductive film 400 are anisotropically dry-etched. As a result, the columnar first via V1 having a height of 20 nm and the first wire M1 having a height of 20 nm below the first via V1 are formed.

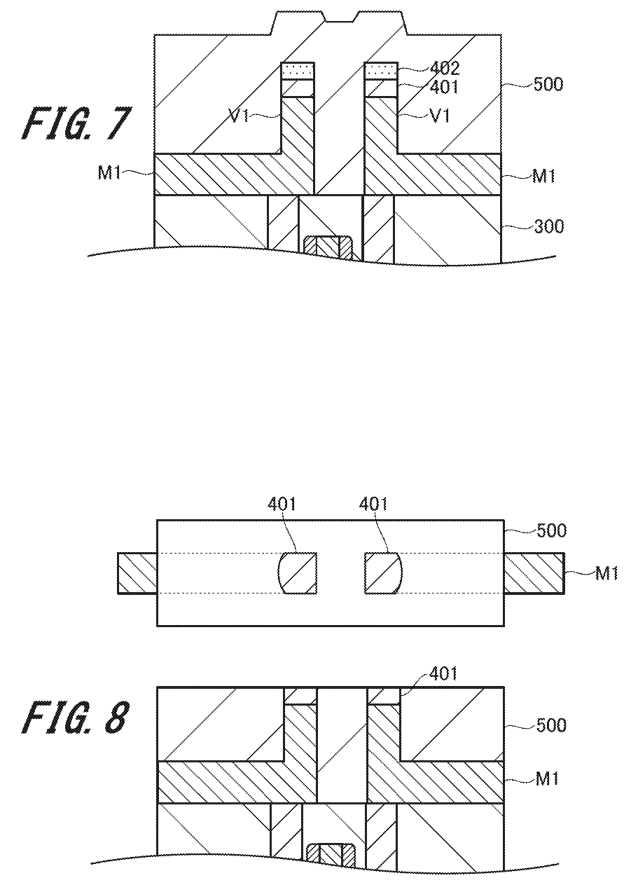

Next, as illustrated in FIG. 7, the first insulating film 500 is formed on the lower insulating film 300 in a state of having the first wire M1, the first via V1, and the patterned conductive hard mask layer 401 and insulating hard mask layer 402 embedded therein. The first insulating film 500 is preferably made of a low dielectric material, and is made of, for example, silicon carboxide (SiOC) having good gap filling characteristics. In addition, in a case of requiring better gap filling characteristics, a methylsilsesquioxane (MSQ) film may be formed by a coating method and cured.

Next, as illustrated in FIG. 8, the first insulating film 500 is subjected to CMP polishing using the conductive hard mask layer 401 as a stopper. As a result, the insulating hard mask layer 402 (see FIG. 7) on the conductive hard mask layer 401 is removed.

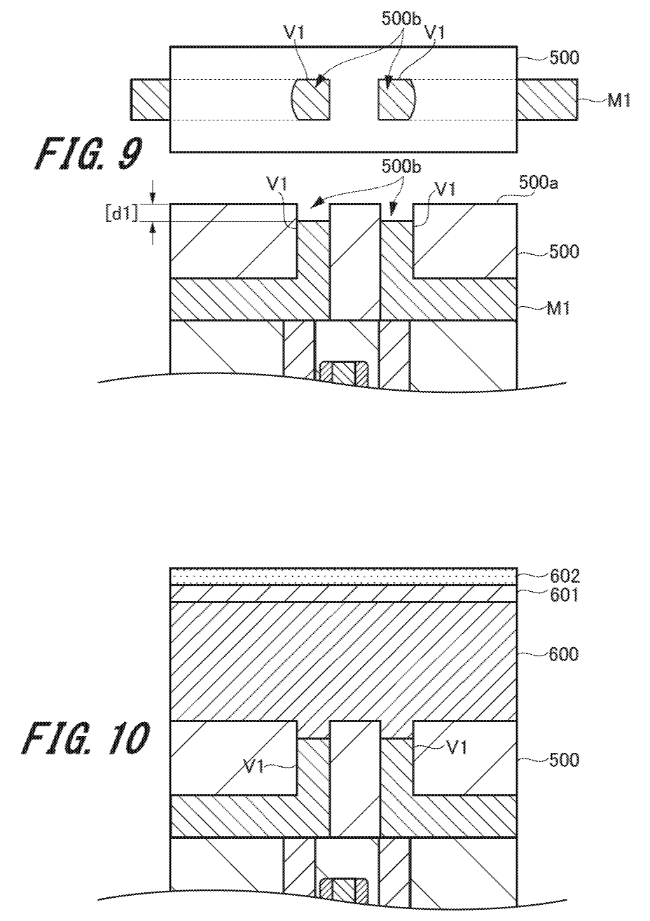

Next, as illustrated in FIG. 9, the conductive hard mask layer 401 (see FIG. 8) formed as a sacrificial layer is removed by etching. The etching may be dry etching or wet etching. As a result, the recess 500b having the first via V1 as a bottom surface is formed on the upper surface 500a side of the first insulating film 500. The depth [d1] of the recess 500b is a size corresponding to the film thickness (here, 5 nm) of the conductive hard mask layer 401, and therefore can have a stable size.

Next, as illustrated in FIG. 10, a second conductive film 600 is formed on the first insulating film 500 and the first via V1. The second conductive film 600 is formed to have a film thickness of about 40 nm using any one of the above-described metal materials other than copper, such as ruthenium (Ru). The film formation is performed by, for example, a physical vapor deposition (PVD) method. In a case where it is difficult to fill the recess, the recess may be filled only with a laminated film by an atomic layer deposition (ALD) method and a PVD method or only with a film formed by an ALD method. In addition, an upper surface of the second conductive film 600 may be planarized by CMP after film formation. Thereafter, a conductive hard mask layer 601 and an insulating hard mask layer 602 are formed in this order above the second conductive film 600. As the conductive hard mask layer 601, for example, a film of titanium nitride (TiN) is formed to have a film thickness of 5 nm. As the insulating hard mask layer 602, for example, a film of silicon nitride (SiN) is formed to have a film thickness of 5 to 10 nm. The film of titanium nitride (TiN) is formed by, for example, a PVD method. The film of silicon nitride (SiN) is formed by, for example, a plasma-enhanced chemical vapor deposition (PECVD) method.

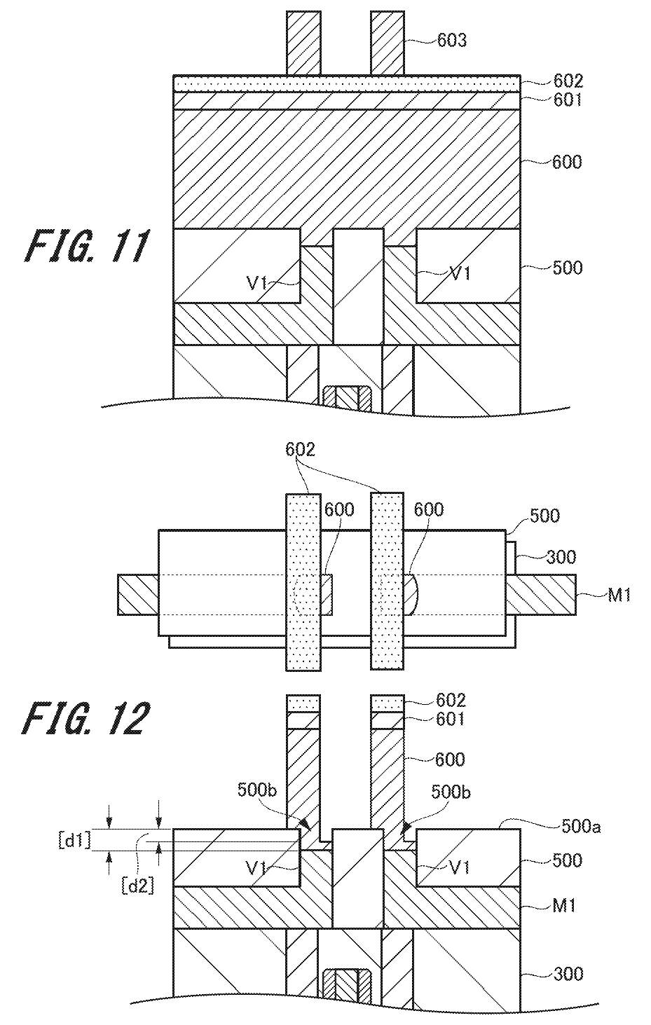

Next, as illustrated in FIG. 11, a resist pattern 603 is formed on the insulating hard mask layer 602. The resist pattern 603 has, for example, a wire shape in which a wire pitch is 20 nm and a minimum line and space (L/S) is 10 nm/10 nm. In addition, the resist pattern 603 is formed to be aligned so as to completely overlap the first via V1. Note that, in a semiconductor manufacturing process with a wire pitch of 20 nm, an allowable value of alignment is 15%.

Next, as illustrated in FIG. 12, using the resist pattern 603 (see FIG. 11) as a mask, the insulating hard mask layer 602, the conductive hard mask layer 601, and the second conductive film 600 are anisotropically dry-etched in this order, and the second conductive film 600 is patterned into the shape of the second wire. The second conductive film 600 is etched in two stages as follows in consideration of a case where positional deviation occurs in the resist pattern 603 with respect to the first via V1 due to misalignment at the time of forming the resist pattern 603.

First, in the first-stage etching, the second conductive film 600 is etched until the first insulating film 500 is exposed. Whether or not the first insulating film 500 is exposed is determined by detecting a decrease in intensity of a specific wavelength using, for example, an optical endpoint system.

Thereafter, in the second-stage etching, the second conductive film 600 is etched such that the second conductive film 600 remains on the entire upper end surface V1a of the first via V1 constituting a bottom surface of the recess 500b in a portion where the recess 500b of the first insulating film 500 is exposed by misalignment. At this time, etching of the second conductive film 600 is advanced such that the step [d2] between the upper surface 500a of the first insulating film 500 and the joint portion M2a of the second wire M2 is 1/2 or more of the depth [d1] of the recess 500b and 30% or more of the minimum wire interval [s1] as described above. The second-stage etching is controlled by an etching time.

Note that, in a case where the second-stage etching is performed so as to obtain the predetermined depth [d2], in order to leave the second conductive film 600 on the entire bottom surface of the recess 500b, the original depth [d1] of the recess 500b needs to be equal to or more than the predetermined depth [d2]. As described with reference to FIG. 9, the depth [d1] of the recess 500b corresponds to the film thickness of conductive hard mask layer 401, and therefore can be set to an accurate depth. Therefore, the second-stage etching can be performed so as to leave the second conductive film 600 on the entire bottom surface of the recess 500b by controlling an etching time.

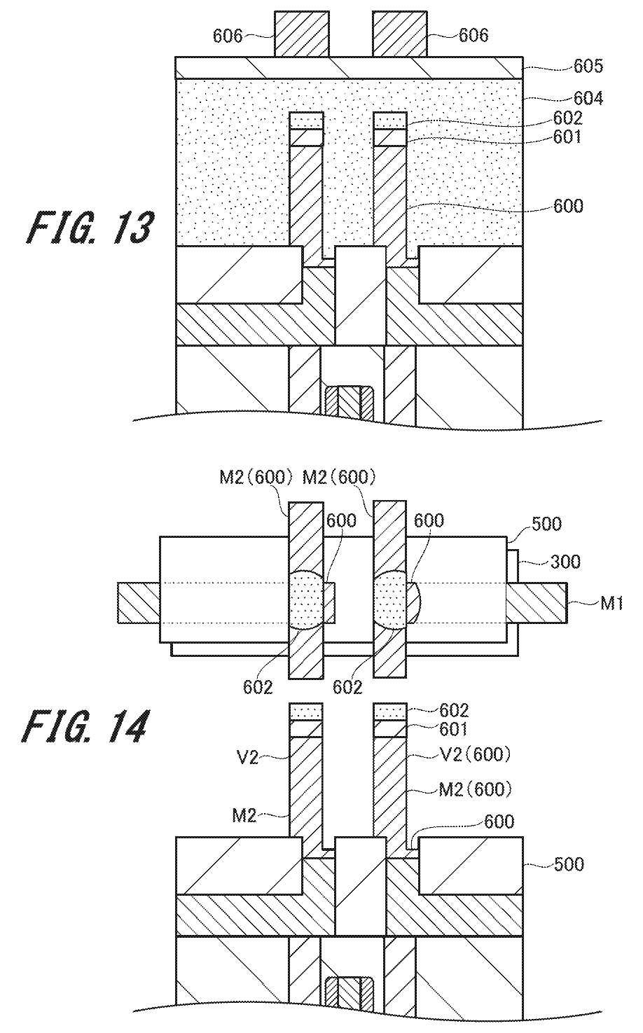

Next, as illustrated in FIG. 13, an organic film 604 is formed by coating so as to have the patterned second conductive film 600, conductive hard mask layer 601, and insulating hard mask layer 602 embedded therein, planarized, and then cured. Above the organic film 604, an LTO film 605 is formed by a PECVD method. Above the LTO film 605, an antireflection film (not illustrated and not described below) is further formed. Thereafter, a via pattern mask 606 made of a resist material is formed by a lithography technique. The via pattern mask 606 is formed to be larger than a line width of the second wire (patterned second conductive film 600).

Next, using the via pattern mask 606 as a mask, the LTO film 605, the organic film 604, the insulating hard mask layer 602, and the conductive hard mask layer 601 are anisotropically dry-etched in this order. Subsequently, the remaining via pattern mask 606, LTO film 605, and organic film 604 are stripped. Thereafter, as illustrated in FIG. 14, using the insulating hard mask layer 602 as a mask, the conductive hard mask layer 601 and a portion located 20 nm above the second conductive film 600 are anisotropically dry-etched. As a result, the columnar second via V2 having a height of 20 nm and the second wire M2 having a height of 20 nm below the second via V2 are formed. After the etching, the remaining organic film 604 (see FIG. 13) is removed by ashing processing.

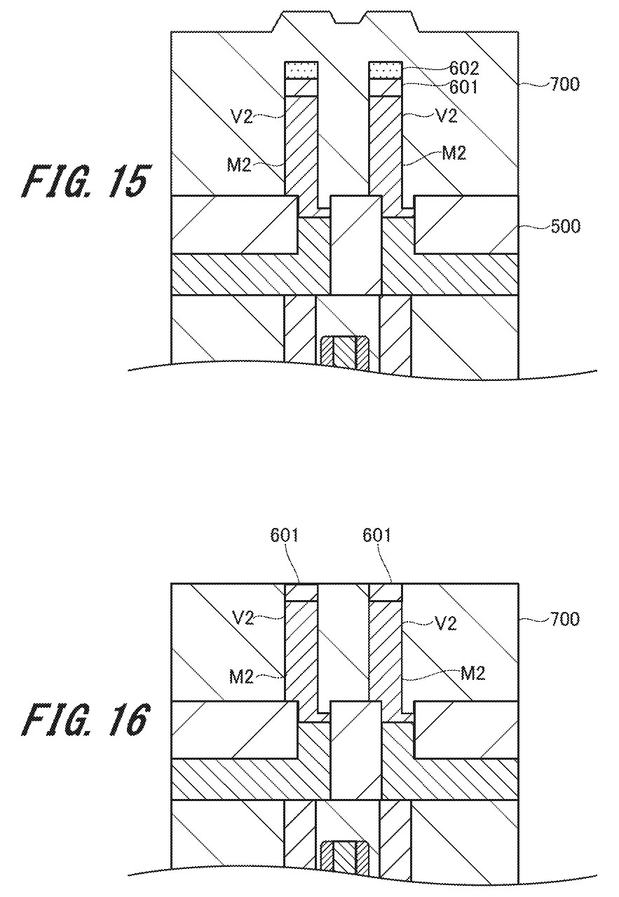

Next, as illustrated in FIG. 15, the second insulating film 700 is formed on the first insulating film 500 in a state of having the second wire M2, the second via V2, and the patterned conductive hard mask layer 601 and insulating hard mask layer 602 embedded therein. The second insulating film 700 is preferably made of a low dielectric material, and is made of, for example, silicon oxycarbide (SiOC) having good gap filling characteristics.

Next, as illustrated in FIG. 16, the second insulating film 700 is subjected to CMP polishing using the conductive hard mask layer 601 as a stopper. As a result, the insulating hard mask layer 602 (see FIG. 15) on the conductive hard mask layer 601 is removed.

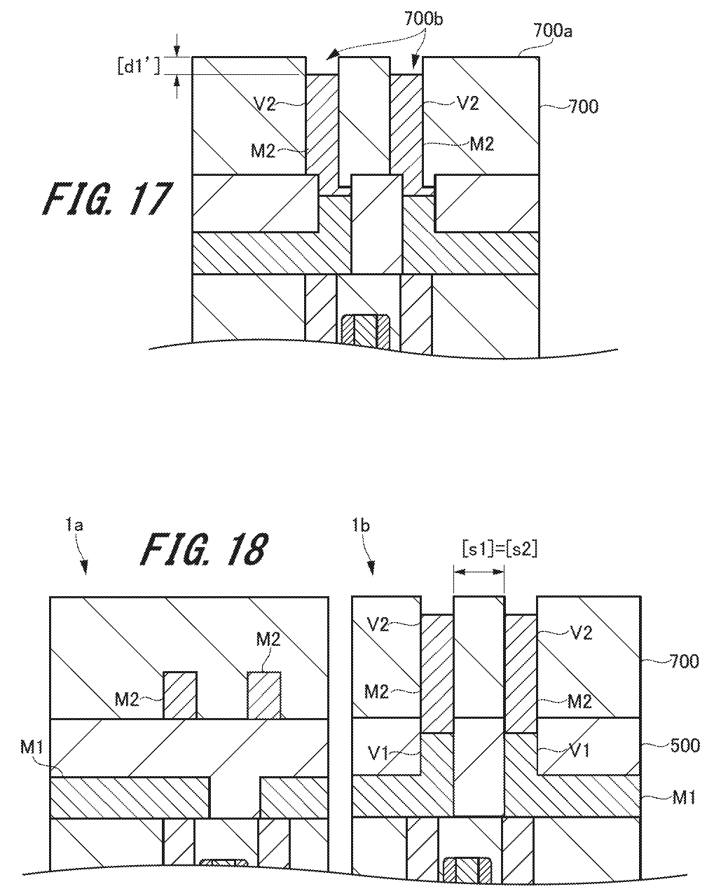

Next, as illustrated in FIG. 17, the conductive hard mask layer 601 (see FIG. 16) is removed by etching. The etching may be dry etching or wet etching. As a result, a recess 700b having the second via V2 as a bottom surface is formed on an upper surface 700a side of the second insulating film 700. A depth [d1'] of the recess 700b is a size corresponding to the film thickness (here, 5 nm) of the conductive hard mask layer 601, and therefore has a stable size.

After the above step, by repeating the steps described with reference to FIGS. 10 to 16, a wire and a via in an upper layer are further formed. Note that, in a case where the formed via is in the uppermost layer, the conductive hard mask layer 601 illustrated in FIG. 16 does not have to be removed, and the conductive hard mask layer 601 does not have to be formed.

FIG. 18 is a cross-sectional view of another portion in the semiconductor device 1 of the first embodiment, and is a diagram illustrating a cross section of a first portion 1a in which the first via V1 and the second via V2 are not formed and a cross section of a second portion 1b in which misalignment between the first via V1 and the second wire M2 does not occur. As illustrated in the second portion 1b, in a case where misalignment does not occur, the substantial shortest distance [s2] between the first via V1 and the second wire M2 is maintained at the minimum wire interval [s1].

### Effect of first embodiment

According to the first embodiment described above, even in a portion where misalignment between the first via V1 and the second wire M2 occurs, the second wire M2 is joined to the entire upper end surface V1a of the first via V1 in the recess 500b having the first via V1 as a bottom surface. As a result, even in a case where misalignment occurs, it is possible to suppress an upper layer of connection resistance between the first via V1 and the second wire M2.

In addition, in a portion where misalignment occurs, the second wire M2 has the joint portion M2a located lower than the upper surface 500a of the first insulating film 500 in the recess 500b. As a result, as compared with a case where the upper end surface V1a of the joint portion M2a or the first via V1 is at the same height as the upper surface of the first insulating film 500, it is possible to increase a substantial distance between an arbitrary first via V1 and the second wire M2 above a first via V1 adjacent to the arbitrary first via V1.

This will be specifically described with reference to FIG. 2. For example, it is assumed that a wire pitch is 20 nm (L/S=10/10nm) and positional deviation between the first via V1 and the second wire M2 due to misalignment is 2 nm, which exceeds 1.5 nm as an allowable value of 15%. In this case, a shortest distance [s2'] in a case where the upper end surface V1a of the joint portion M2a or the first via V1 is at the same height as the upper surface of the first insulating film 500 and there is no step [d2] is 8 nm, which is 80% of the minimum wire interval [s1] =10 nm.

On the other hand, in a case where the depth [d1] of the recess 500b = 4 nm and the step [d2] = 3 mn, the shortest distance [s2] between a first via V1 and a second wire M2 adjacent to each other is about 8.54 nm. This value is 85.4% of the minimum wire interval [s1] =10 nm, and the shortest distance [s2] can be increased by 5.4% as compared with the case where there is no step [d2]. As a result, the shortest distance [s2] which is 8.5 nm or more of an allowable value can be achieved.

Furthermore, in a case where the depth [d1] of the recess 500b = 6 nm and the step [d2] = 4 mn, the shortest distance [s2] between a first via V1 and a second wire M2 adjacent to each other is about 8.94 nm. This value is 89.4% of the minimum wire interval [s1] =10 nm, and the shortest distance [s2] can be increased by 9.4% as compared with the case where there is no step [d2]. As a result, the shortest distance [s2] which is 8.5 nm or more of an allowable value can be achieved with a margin.

Furthermore, the first wire M1 and the first via V1 are embedded with the first insulating film 500 having no interface, and the second wire M2 and the second via V2 are embedded with the single second insulating film 700 having no interface. Therefore, it is also possible to ensure TDDB characteristics between adjacent first vias V1 and between adjacent second vias V2.

Note that, in the above, an example of the wire pitch of 20 nm (L/S = 10/10nm) has been described, but a similar effect can be obtained even in a case of a pitch less than the wire pitch.

### Second Embodiment

### Configuration of semiconductor device of second embodiment

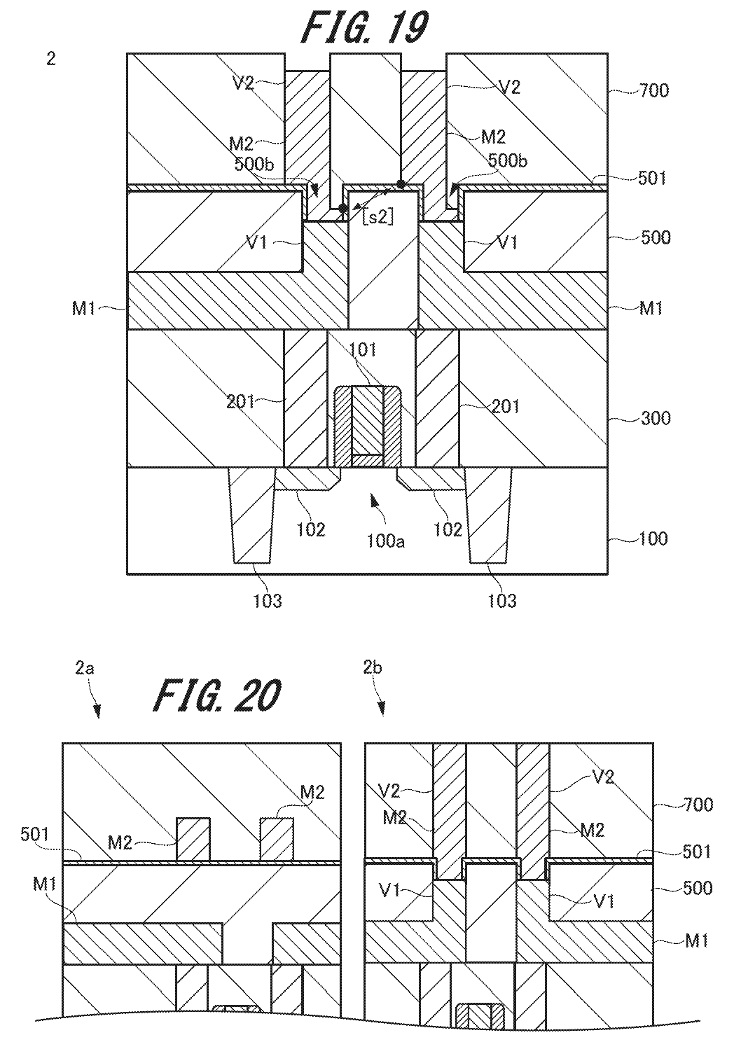

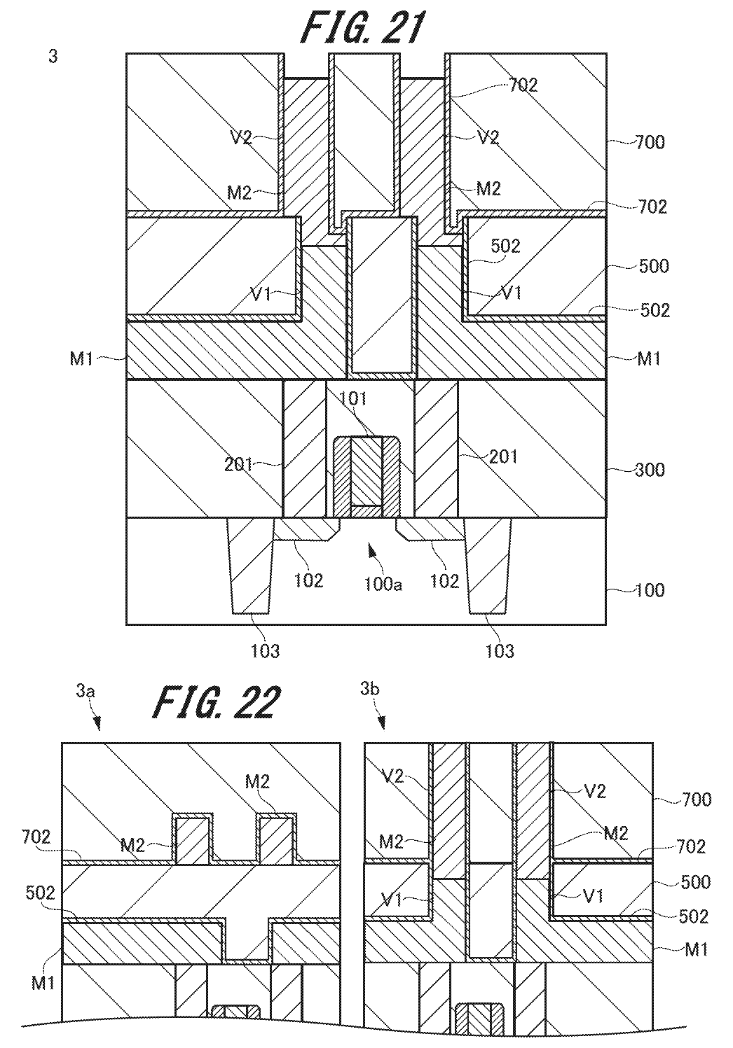

FIG. 19 is a cross-sectional view of a main portion of a semiconductor device 2 of a second embodiment, and is a diagram illustrating a portion where misalignment between a first via V1 and a second wire M2 occurs. FIG. 20 is a cross-sectional view of another portion in the semiconductor device 2 of the second embodiment, and is a diagram illustrating a cross section of a first portion 2a in which the first via V1 and a second via V2 are not formed and a cross section of a second portion 2b in which misalignment between the first via V1 and the second wire M2 does not occur.

A difference of the semiconductor device 2 of the second embodiment illustrated in FIGS. 19 and 20 from the semiconductor device of the first embodiment is that a barrier insulating layer 501 is formed so as to cover a first insulating film 500 on the first via V1, and the other components are similar.

The barrier insulating layer 501 is a layer made of aluminum oxide (AlOx), and is formed on an upper surface of the first insulating film 500 and a sidewall of a recess 500b.

### Method for manufacturing semiconductor device of second embodiment

In a method for manufacturing the semiconductor device 2 of the second embodiment as described above, it is only required to perform a step of forming the barrier insulating layer 501 after the step described with reference to FIG. 9 in the method for manufacturing the semiconductor device of the first embodiment and before the step described with reference to FIG. 10.

In the step of forming the barrier insulating layer 501, an insulating material such as aluminum oxide (AlOx) is selectively formed on an exposed surface of the first insulating film 500. This selective formation can be performed, for example, by forming a self-assembled monolayer (SAM) on a metal (on the first via V1), then forming a film of aluminum oxide (AlOx), and then removing the SAM on the first via V1.

Note that, in a case of forming an upper wiring structure on the configuration illustrated in FIGS. 19 and 20, first, a barrier insulating layer is formed as described above so as to cover the second insulating film 700. Thereafter, it is only required to repeat the steps described with reference to FIGS. 10 to 16.

### Effect of second embodiment

According to the second embodiment described above, the sidewall of the recess 500b is covered with the barrier insulating layer 501, and in the misalignment portion illustrated in FIG. 19, the barrier insulating layer 501 is formed at the shortest distance between the first via V1 and the second wire M2 adjacent to the first via V1. As a result, a breakdown voltage between the first via V1 and the second wire M2 is increased, and in addition to the effect of the first embodiment, an effect of making the TDDB life longer than that of the first embodiment can be obtained. In addition, by covering the first insulating film 500 with the barrier insulating layer 501, moisture absorption of the first insulating film 500 can be prevented, and plasma damage to the first insulating film 500 can be prevented in an upper layer processing step.

### Third Embodiment

### Configuration of semiconductor device of third embodiment

FIG. 21 is a cross-sectional view of a main portion of a semiconductor device 3 of a third embodiment, and is a diagram illustrating a portion where misalignment between a first via V1 and a second wire M2 occurs. FIG. 22 is a cross-sectional view of another portion in the semiconductor device 3 of the third embodiment, and is a diagram illustrating a cross section of a first portion 3a in which the first via V1 and a second via V2 are not formed and a cross section of a second portion 3b in which misalignment between the first via V1 and the second wire M2 does not occur.

A difference of the semiconductor device 3 of the third embodiment illustrated in FIGS. 21 and 22 from the semiconductor device of the first embodiment is that a first base barrier insulating layer 502 is formed under a first insulating film 500, and a second base barrier insulating layer 702 is formed under the second insulating film 700, and the other components are similar.

The first base barrier insulating layer 502 and the second base barrier insulating layer 702 are layers made of, for example, plasma silicon carbonitride (SiCN). The first base barrier insulating layer 502 is a layer formed before formation of the first insulating film 500, and is formed under the first insulating film 500 and on a sidewall portion of the first insulating film 500. In addition, the second base barrier insulating layer 702 is a layer formed before formation of the second insulating film 700, and is formed under the second insulating film 700 and on a sidewall portion of the second insulating film 700.

### Method for manufacturing semiconductor device of third embodiment

In a method for manufacturing the semiconductor device 3 of the third embodiment as described above, a step of forming the first base barrier insulating layer 502 is performed after the step described with reference to FIG. 6 in the method for manufacturing the semiconductor device of the first embodiment and immediately before the step of forming the first insulating film 500 described with reference to FIG. 7. The first base barrier insulating layer 502 on the first via V1 is removed when the first insulating film 500 is subjected to CMP polishing in the next step illustrated in FIG. 8, but the first base barrier insulating layer 502 is left on the sidewall of the recess 500b when the conductive hard mask layer 401 is removed by etching.

In addition, in the method for manufacturing the semiconductor device 3, a step of forming the second base barrier insulating layer 702 is performed after the step described with reference to FIG. 14 in the method for manufacturing the semiconductor device of the first embodiment and immediately before the step of forming the second insulating film 700 described with reference to FIG. 15. The second base barrier insulating layer 702 on the second via V2 is removed when the second insulating film 700 is subjected to CMP polishing in the next step illustrated in FIG. 16, but the second base barrier insulating layer 702 is left on the sidewall of the recess 700b when the conductive hard mask layer 601 is removed by etching.

### Effect of third embodiment

According to the third embodiment described above, exposed surfaces of the first wire M1 and the first via V1 are covered with the first base barrier insulating layer 502, and exposed surfaces of the second wire M2 and the second via V2 are covered with the second base barrier insulating layer 702. As a result, the breakdown voltages of the first insulating film 500 and the second insulating film 700 are compensated by the first base barrier insulating layer 502 and the second base barrier insulating layer 702. As a result, in addition to the effect of the first embodiment, an effect of making the TDDB life longer than that of the first embodiment can be obtained. In addition, metal materials such as the first wire M1 and the first via V1 are covered with the first base barrier insulating layer 502. Therefore, metal corrosion can be prevented, and plasma damage in an upper layer processing step. In addition, the first base barrier insulating layer 502 and the second base barrier insulating layer 702 are blanket formed films on the entire surface, and therefore it is possible to perform stable film formation as compared with the second embodiment in which selective film formation is performed.

### Fourth Embodiment

### Configuration of semiconductor device of fourth embodiment

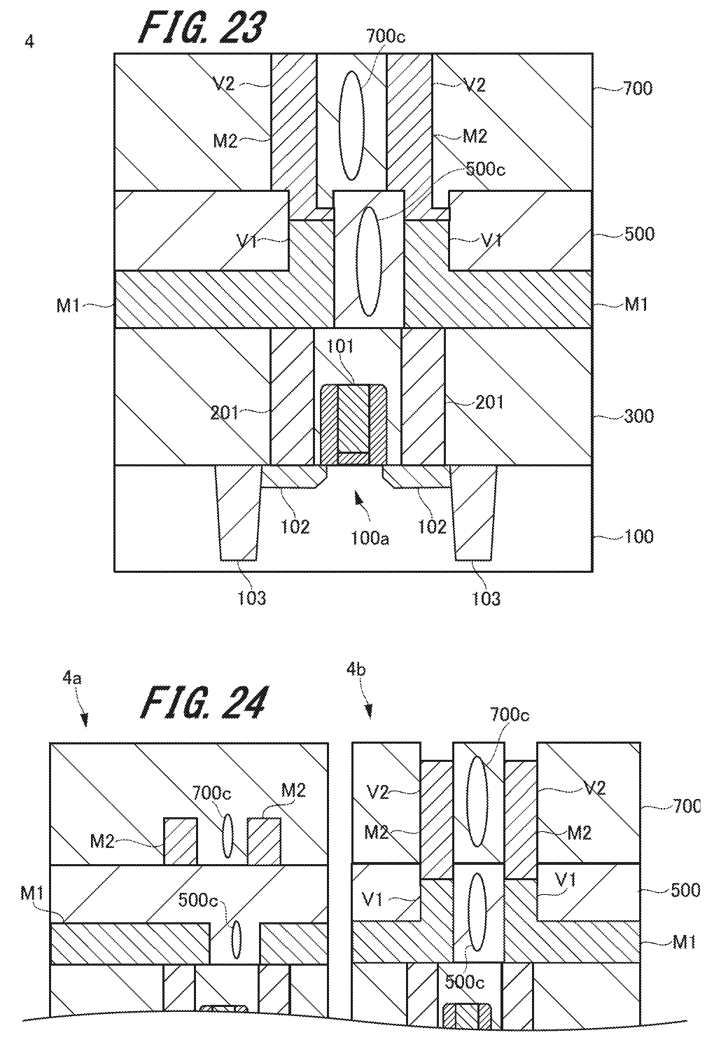

FIG. 23 is a cross-sectional view of a main portion of a semiconductor device 4 of a fourth embodiment, and is a diagram illustrating a portion where misalignment between a first via V1 and a second wire M2 occurs. FIG. 24 is a cross-sectional view of another portion in the semiconductor device 4 of the fourth embodiment, and is a diagram illustrating a cross section of a first portion 4a in which the first via V1 and a second via V2 are not formed and a cross section of a second portion 4b in which misalignment between the first via V1 and the second wire M2 does not occur.

A difference of the semiconductor device 4 of the fourth embodiment illustrated in FIGS. 23 and 24 from the semiconductor device of the first embodiment is that a first insulating film 500 has an airgap 500c and a second insulating film 700 has an airgap 700c, and the other components are similar.

The airgap 500c of the first insulating film 500 is formed between the first wires M1 and between the first vias V1. These airgaps 500c are closed in the first insulating film 500 and have a height smaller than the film thickness of the first insulating film 500. The airgap 700c of the second insulating film 700 is formed between the second wires M2 and between the second vias V2. These airgaps 700c are closed in the second insulating film 700 and have a height smaller than the film thickness of the second insulating film 700.

### Method for manufacturing semiconductor device of fourth embodiment

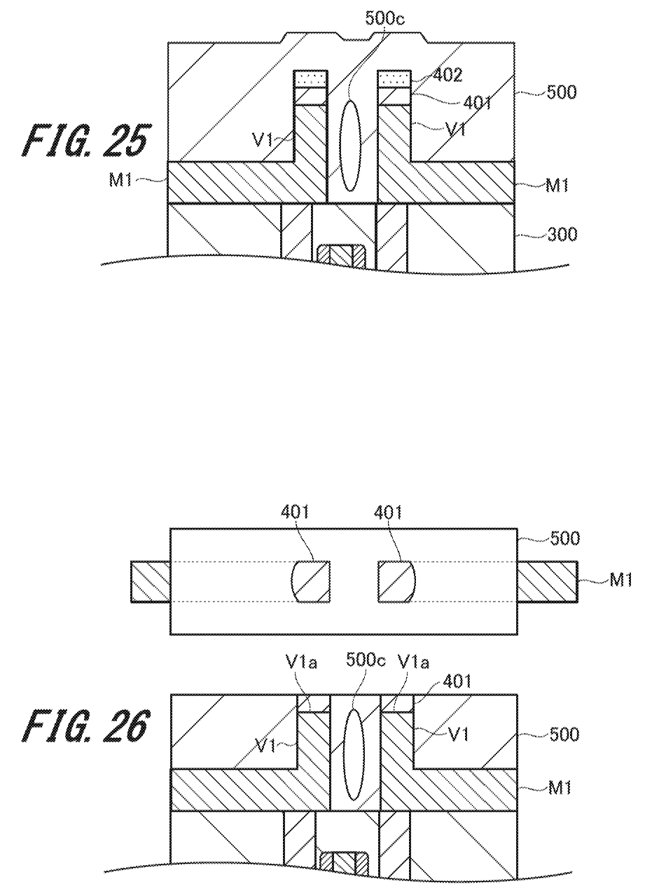

FIGS. 25 and 26 are process diagrams (part 1) and (part 2) illustrating a method for manufacturing the semiconductor device of the fourth embodiment, and are diagrams corresponding to the steps described with reference to FIGS. 7 and 8 in the method for manufacturing the semiconductor device of the first embodiment. In the method for manufacturing the semiconductor device 4 of the fourth embodiment as described above, when the first insulating film 500 described with reference to FIG. 7 is formed in the method for manufacturing the semiconductor device of the first embodiment, a film forming method having poor gap filling characteristics is applied. As a result, as illustrated in FIG. 25, the first insulating film 500 having the airgap 500c is formed.

At this time, the first insulating film 500 is formed on the lower insulating film 300 in a state of having the first wire M1, the first via V1, and the patterned conductive hard mask layer 401 and insulating hard mask layer 402 embedded therein. In addition, the first insulating film 500 is preferably made of a low dielectric material, and is made of, for example, silicon carboxide (SiOC) as in the first embodiment.

In addition, in the formation of the first insulating film 500, the gap filling characteristics are controlled such that the airgap 500c is located lower than an upper surface of the conductive hard mask layer 401. As a result, as illustrated in FIG. 26, when the first insulating film 500 is subjected to CMP polishing using the conductive hard mask layer 401 as a stopper, the airgap 500c is maintained in a closed state in the first insulating film 500. In addition, by using the conductive hard mask layer 401 as a stopper, CMP polishing can be stopped at a position higher than the upper end surface V1a of the first via V1 by the height of the conductive hard mask layer 401. This brings about an advantage that the airgap 500c can be formed at a higher position. In addition, infiltration of a slurry into the airgap 500c at the time of CMP polishing is prevented. In addition, in the subsequent steps, it is possible to prevent infiltration of an etching gas or an etching liquid into the airgap 500c when the conductive hard mask layer 401 is stripped, and it is possible to eliminate an influence of the infiltration.

Note that, although not illustrated here, the step of forming the second insulating film 700 described with reference to FIG. 15 in the method for manufacturing the semiconductor device of the first embodiment is also performed similarly to the above-described formation of the first insulating film 500.

### Effect of fourth embodiment

According to the fourth embodiment described above, by forming the airgaps 500c and 700c in the first insulating film 500 and the second insulating film 700, respectively, in addition to the effect of the first embodiment, it is possible to obtain an effect that an inter-wire capacitance can be reduced. In addition, in the step of forming the first insulating film 500, the gap filling characteristics are controlled such that the airgap 500c is located lower than an upper surface of the conductive hard mask layer 401. The airgap 500c is not opened to the outside of the first insulating film 500, and the subsequent steps can be advanced without being affected by the airgap 500c. The same applies to a step of forming the second insulating film 700. Furthermore, the CMP polishing of the first insulating film 500 has an advantage that the CMP polishing can be stopped at a position higher than the upper end surface V1a of the first via V1 by using the conductive hard mask layer 401 as a stopper, and the airgap 500c can be formed at a higher position. The same applies to a CMP polishing step for the second insulating film 700.

Note that the fourth embodiment can be combined with the second embodiment and the third embodiment, and the effects of the second embodiment and the third embodiment can be obtained by the combination.

### Fifth Embodiment

### Configuration of semiconductor device of fifth embodiment

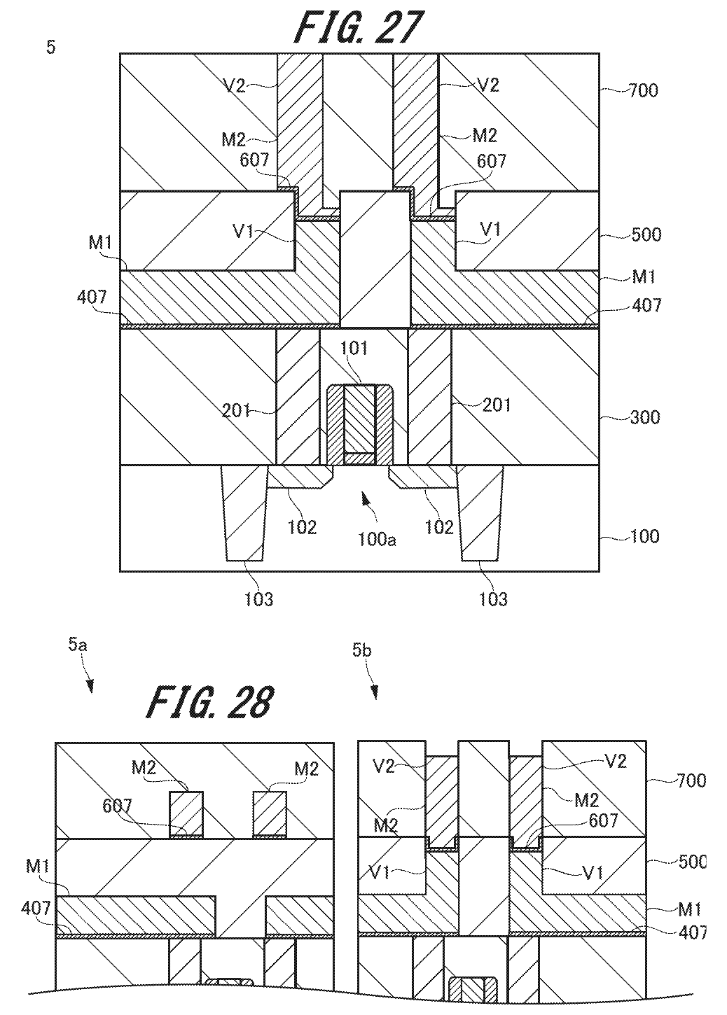

FIG. 27 is a cross-sectional view of a main portion of a semiconductor device 5 of a fifth embodiment, and is a diagram illustrating a portion where misalignment between a first via V1 and a second wire M2 occurs. FIG. 28 is a cross-sectional view of another portion in the semiconductor device 5 of the fifth embodiment, and is a diagram illustrating a cross section of a first portion 5a in which the first via V1 and a second via V2 are not formed and a cross section of a second portion 5b in which misalignment between the first via V1 and the second wire M2 does not occur.

A difference of the semiconductor device 5 of the fifth embodiment illustrated in FIGS. 27 and 28 from the semiconductor device of the first embodiment is that a first barrier metal layer 407 is formed below a first wire M1, and a second barrier metal layer 607 is formed below the second wire M2, and the other components are similar.

The first barrier metal layer 407 and the second barrier metal layer 607 are layers made of, for example, titanium (Ti), titanium nitride (TiN), tantalum (Ta), tantalum nitride (TaN), molybdenum nitride (MoN), ruthenium nitride (RuN), or tungsten nitride (WN). In addition, the second barrier metal layer 607 is formed on a bottom surface of the second wire M2 and a sidewall of a recess 500b.

### Method for manufacturing semiconductor device of fifth embodiment

In a method for manufacturing the semiconductor device 5 of the fifth embodiment as described above, a step of forming the first barrier metal layer 407 is performed before the first conductive film 400 in the step described with reference to FIG. 3 is formed in the method for manufacturing the semiconductor device of the first embodiment. Subsequently, in the step described with reference to FIG. 4, it is only required to etch the first barrier metal layer 407 under the first conductive film 400 following the anisotropic dry etching of the first conductive film 400.

In addition, a step of forming the second barrier metal layer 607 is performed before the second conductive film 600 in the step described with reference to FIG. 10 is performed. Thereafter, in the step described with reference to FIG. 12, it is only required to etch the second barrier metal layer 607 under the second conductive film 600 following the anisotropic dry etching of the second conductive film 600.

### Effect of fifth embodiment

According to the fifth embodiment described above, by forming the first barrier metal layer 407 below the first wire M1 and forming the second barrier metal layer 607 below the second wire M2, it is possible to improve contact resistance between the first wire M1 and the plug 201 and to improve contact resistance between the second wire M2 and the first via V1. In addition, it is possible to improve adhesion between the first wire M1 and each of the plug 201 and the lower insulating film 300, and to improve adhesion between the second wire M2 and each of the first via V1 and the first insulating film 500.

Note that the fifth embodiment can be combined with the second to fourth embodiments. The fourth embodiment in this case also includes a combination with the second embodiment or the third embodiment. The fifth embodiment can obtain the effects of these embodiments by being combined with these embodiments.

### Sixth Embodiment

### Configuration of semiconductor device of sixth embodiment

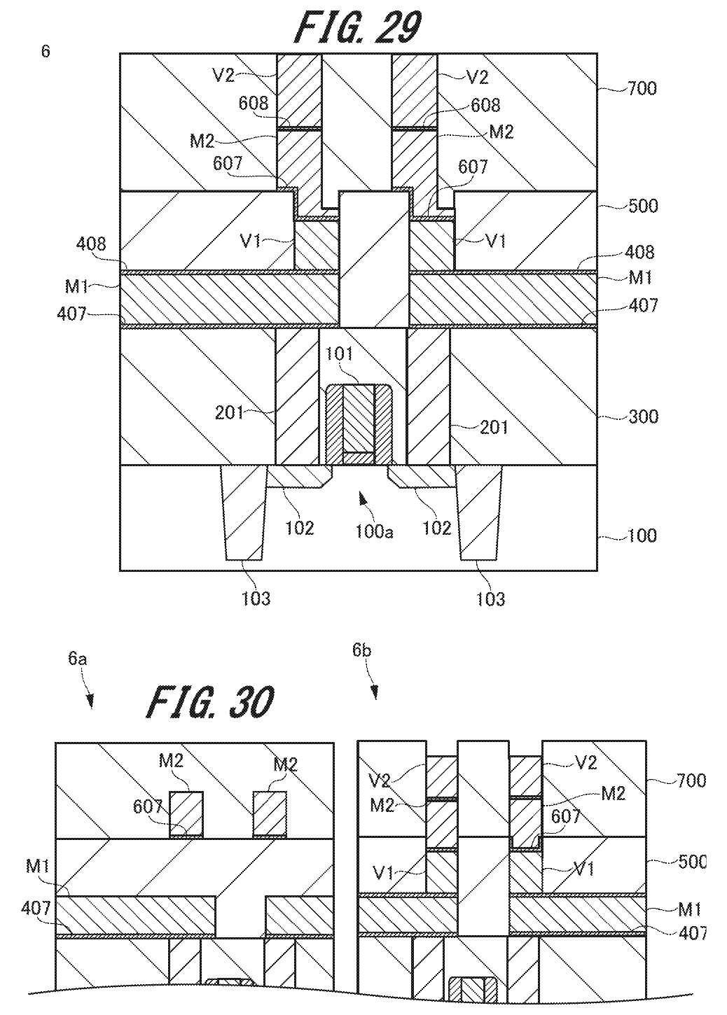

FIG. 29 is a cross-sectional view of a main portion of a semiconductor device 6 of a sixth embodiment, and is a diagram illustrating a portion where misalignment between a first via V1 and a second wire M2 occurs. FIG. 30 is a cross-sectional view of another portion in the semiconductor device 6 of the sixth embodiment, and is a diagram illustrating a cross section of a first portion 6a in which the first via V1 and a second via V2 are not formed and a cross section of a second portion 6b in which misalignment between the first via V1 and the second wire M2 does not occur.

The semiconductor device 6 of the sixth embodiment illustrated in FIGS. 29 and 30 has an intermediate barrier metal layer 408 between the first wire M1 and the first via V1 of the semiconductor device of the fifth embodiment, and has an intermediate barrier metal layer 608 between the second wire M2 and the second via V2.

The intermediate barrier metal layers 408 and 608 are layers made of a material similar to that of the first barrier metal layer 407 and the second barrier metal layer 607, for example, titanium (Ti), titanium nitride (TiN), tantalum (Ta), tantalum nitride (TaN), molybdenum (Mo), molybdenum nitride (MoN), ruthenium nitride (RuN), or tungsten nitride (WN). In addition, the intermediate barrier metal layer 408 may be formed on the entire surface of the first wire M1, and the intermediate barrier metal layer 608 may be formed on the entire surface of the second wire M2.

### Method for manufacturing semiconductor device of sixth embodiment

In a method for manufacturing the semiconductor device 6 of the sixth embodiment as described above, a step of forming the first barrier metal layer 407 is performed before the first conductive film 400 in the step described with reference to FIG. 3 is formed in the method for manufacturing the semiconductor device of the first embodiment. Subsequently, the intermediate barrier metal layer 408 (see FIGS. 29 and 30) is formed at an intermediate position where the first conductive film 400 having a total film thickness of 40 nm is formed. Thereafter, in the step described with reference to FIG. 4, the first barrier metal layer 407 under the first conductive film 400 is etched following the anisotropic dry etching of the first conductive film 400 via the intermediate barrier metal layer 408.

In addition, it is only required to perform the steps up to the step of forming the columnar first via V1 and the first wire M1 below the first via V1 illustrated in FIG. 6 in a similar manner to the procedure described in the first embodiment. In this procedure, particularly when the conductive hard mask layer 401 and an upper portion of the first conductive film 400 are anisotropically dry-etched using the insulating hard mask layer 402 as a mask, the intermediate barrier metal layer 408 is used as an etching stopper as illustrated in FIG. 31. As a result, the columnar first via V1 having a height of 20 nm and the first wire M1 having a height of 20 nm below the first via V1 can be formed with high accuracy.

In addition, in the method for manufacturing the semiconductor device 6 of the sixth embodiment, a step of forming the second barrier metal layer 607 is performed before the second conductive film 600 in the step described with reference to FIG. 10 is formed in the method for manufacturing the semiconductor device of the first embodiment. Subsequently, the intermediate barrier metal layer 608 (see FIGS. 29 and 30) is formed at an intermediate position where the second conductive film 600 having a total film thickness of 40 nm is formed. Thereafter, in the step described with reference to FIG. 12, the second barrier metal layer 607 under the second conductive film 600 is etched following the anisotropic dry etching of the second conductive film 600 via the intermediate barrier metal layer 608.

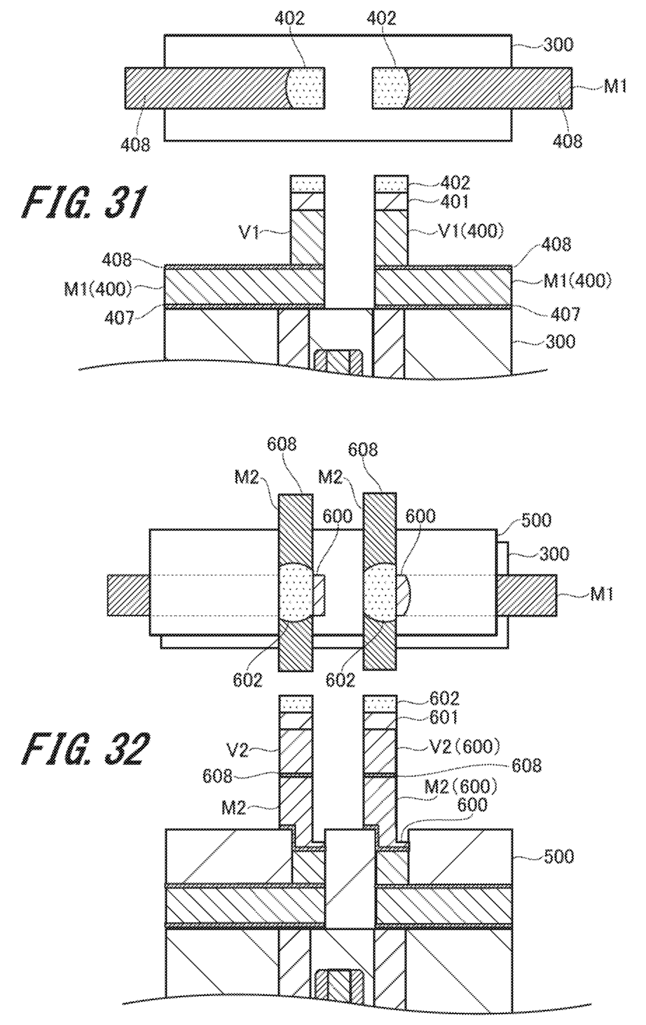

In addition, it is only required to perform the steps up to the step of forming the columnar second via V2 and the second wire M2 below the second via V2 illustrated in FIG. 14 in a similar manner to the procedure described in the first embodiment. In this procedure, particularly when the conductive hard mask layer 601 and an upper portion of the second conductive film 600 are anisotropically dry-etched using the insulating hard mask layer 602 as a mask, the intermediate barrier metal layer 608 is used as an etching stopper as illustrated in FIG. 32. As a result, the columnar second via V2 having a height of 20 nm and the second wire M2 having a height of 20 nm below the second via V2 can be formed with high accuracy.

### Effect of sixth embodiment

According to the sixth embodiment described above, in addition to the effect of the fifth embodiment, the first wire M1, the first via V1, the second wire M2, and the second via V2 can be further formed with favorable height accuracy. As a result, wiring resistance and via resistance in a surface of the semiconductor substrate 100 can be made uniform.

Note that the sixth embodiment can be combined with the second to fourth embodiments. The fourth embodiment in this case also includes a combination with the second embodiment or the third embodiment. The sixth embodiment can obtain the effects of these embodiments by being combined with these embodiments.

### Seventh Embodiment

### Configuration of semiconductor device of seventh embodiment

FIG. 33 is a cross-sectional view of a main portion of a semiconductor device 7 of a seventh embodiment. As illustrated in FIG. 33, a first via V1' does not need to be integrally formed with a wire, and for example, may be joined to an upper portion of a plug 201 connected to a semiconductor substrate. Such a first via V1' is formed in a middle of line (MOL) step which is an intermediate step between an element step and a wiring step.

### Method for manufacturing semiconductor device of seventh embodiment

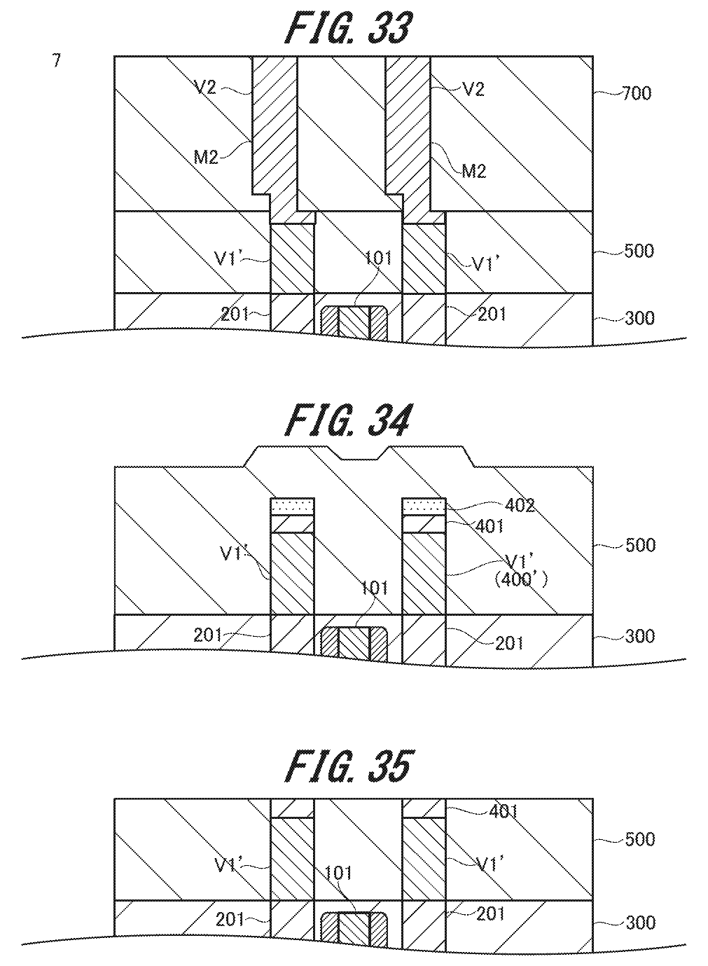

FIGS. 34 to 36 are process diagrams (part 1) to (part 3) illustrating features of a method for manufacturing the semiconductor device of the seventh embodiment. In the method for manufacturing the semiconductor device 7 of the seventh embodiment, first, as illustrated in FIG. 34, the first via V1' is formed in a state of being joined to the plug 201 embedded in the lower insulating film 300. The first via V1' is formed by anisotropic dry etching of a first conductive film 400' formed with a film thickness corresponding to the height of the first via V1'. The first conductive film 400' is made of any one of the metal materials described in the first embodiment, other than copper. In this case, the first via V1' is formed by anisotropic dry etching of the first conductive film 400' having a film thickness of 20 nm and the conductive hard mask layer 401 and the insulating hard mask layer 402 above the first conductive film 400' without performing the step of forming the first wire M1 described with reference to FIGS. 3 and 4 in the first embodiment.

Thereafter, the first insulating film 500 is formed on the lower insulating film 300 in a state of having the first via V1' and the patterned conductive hard mask layer 401 and insulating hard mask layer 402 embedded therein. The first insulating film 500 is preferably made of a low dielectric material, and is made of, for example, silicon carboxide (SiOC) having good gap filling characteristics as in the first embodiment.

Thereafter, it is only required to perform a procedure similar to the procedure described with reference to FIG. 8 and subsequent drawings in the first embodiment. Next, as illustrated in FIG. 35, the first insulating film 500 is subjected to CMP polishing using the conductive hard mask layer 401 as a stopper. As a result, the insulating hard mask layer 402 (see FIG. 34) on the conductive hard mask layer 401 is removed.

Next, as illustrated in FIG. 36, the conductive hard mask layer 401 (see FIG. 35) is removed by etching. The etching may be dry etching or wet etching. As a result, a recess 500b having the first via V1' as a bottom surface is formed on an upper surface 500a side of the first insulating film 500. The depth [d1] of the recess 500b is a size corresponding to the film thickness (here, 5 nm) of the conductive hard mask layer 401, and therefore can have a stable size.

Thereafter, the second wire M2 and the second via V2 are further formed as in the first embodiment.

### Effect of seventh embodiment

Even in the seventh embodiment described above, an effect similar to that of the first embodiment can be obtained.

Note that the seventh embodiment can be combined with the second to sixth embodiments. Note that, since the seventh embodiment does not include the first wire, the seventh embodiment is combined with a portion excluding the configuration related to the first wire in the second to sixth embodiments. The seventh embodiment can obtain the effects of these embodiments by being combined with these embodiments.

### Eighth Embodiment

### Configuration of semiconductor device of eighth embodiment

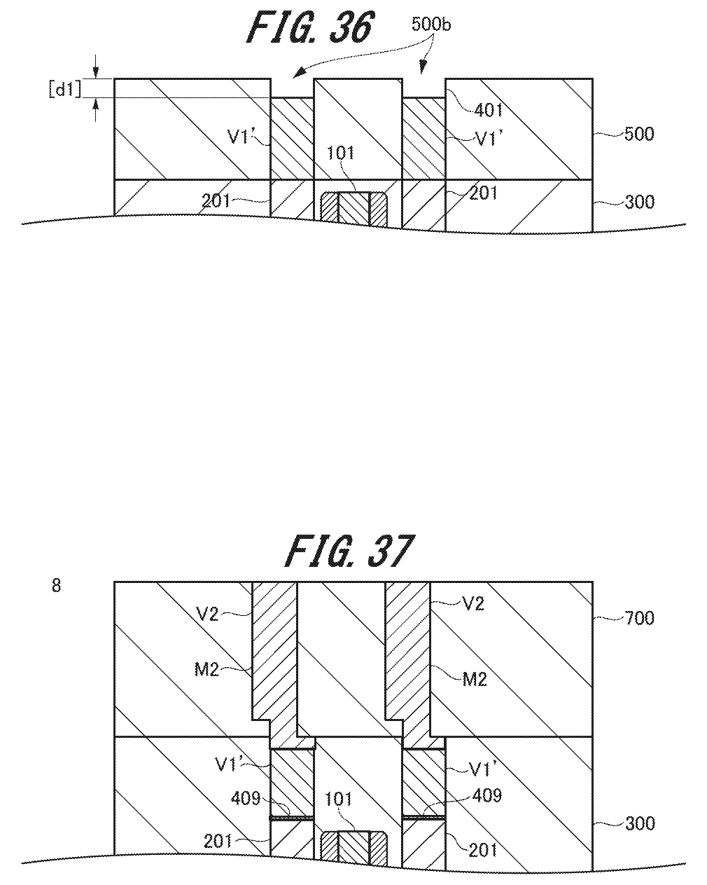

FIG. 37 is a cross-sectional view of a main portion of a semiconductor device 8 of an eighth embodiment. The semiconductor device 8 illustrated in FIG. 37 is a modification of the semiconductor device of the seventh embodiment, and has a base barrier metal layer 409 under a first via V1' and between the first via V1' and a plug 201.

### Method for manufacturing semiconductor device of eighth embodiment

In a method for manufacturing the semiconductor device 8 of the eighth embodiment as described above, it is only required to form the base barrier metal layer 409 before the first conductive film 400' is formed, and to dry-etch the base barrier metal layer 409 following the first conductive film 400' in the anisotropic dry etching when the first via V1' is formed in the method for manufacturing the semiconductor device of the seventh embodiment.

### Effect of eighth embodiment

According to the eighth embodiment described above, by forming the base barrier metal layer 409, it is possible to improve contact resistance and adhesion between the plug 201 and the first via V1'.

Note that the eighth embodiment can be combined with the second to sixth embodiments. Note that, since the eighth embodiment does not include the first wire, the eighth embodiment is combined with a portion excluding the configuration related to the first wire in the second to sixth embodiments. The eighth embodiment can obtain the effects of these embodiments by being combined with these embodiments.

### Ninth Embodiment

### Configuration of semiconductor device of ninth embodiment

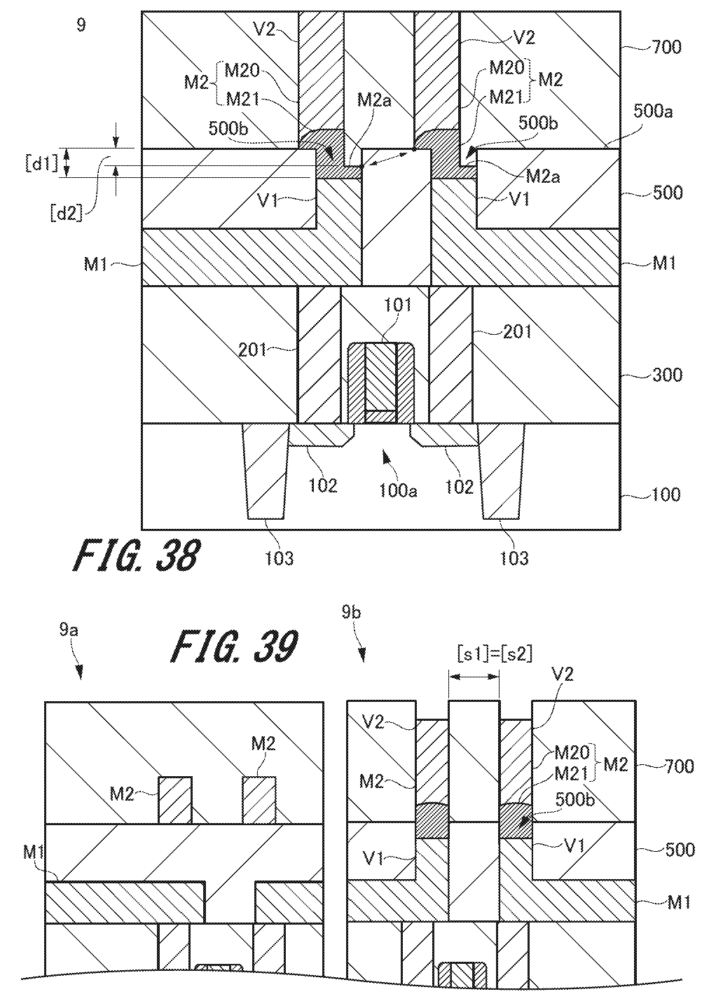

FIG. 38 is a cross-sectional view of a main portion of a semiconductor device 9 of a ninth embodiment, and is a diagram illustrating a portion where misalignment between a first via V1 and a second wire M2 occurs. FIG. 39 is a cross-sectional view of another portion in the semiconductor device 9 of the ninth embodiment, and is a diagram illustrating a cross section of a first portion 9a in which the first via V1 and a second via V2 are not formed and a cross section of a second portion 9b in which misalignment between the first via V1 and the second wire M2 does not occur.

A difference of the semiconductor device 9 of the ninth embodiment illustrated in FIGS. 38 and 39 from the semiconductor device of the first embodiment is that the second wire M2 has a laminated structure made of different conductive materials, and the other components are similar. That is, the second wire M2 includes an anchor portion M21 joined to the first via V1 and a main body layer M20 made of a conductive material different from that of the anchor portion M21.

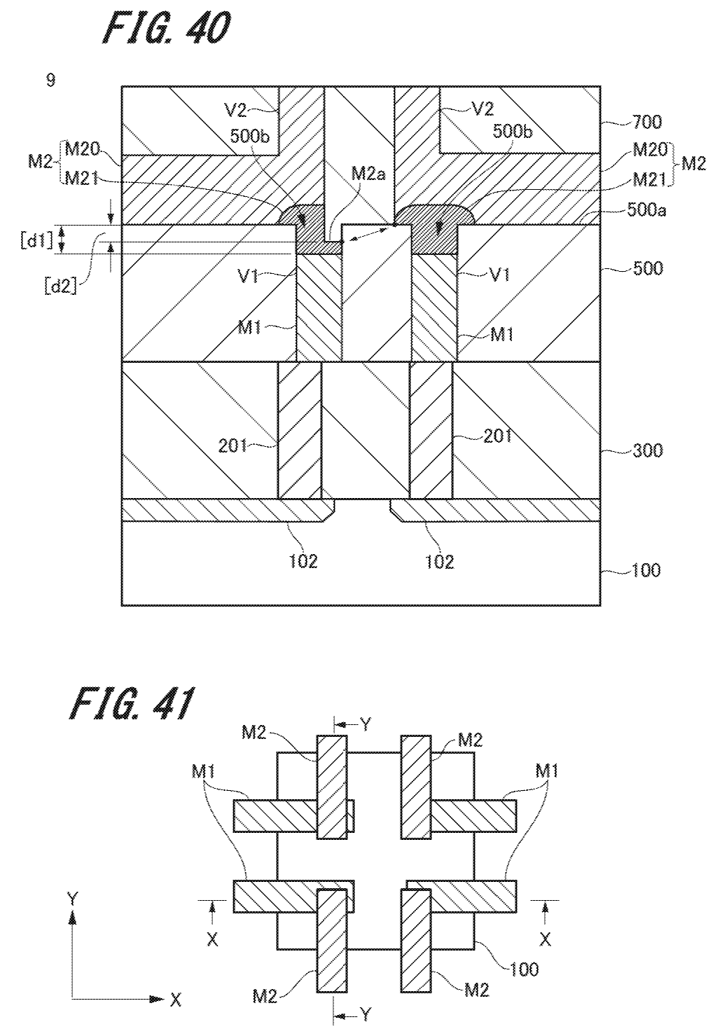

FIG. 40 is a cross-sectional view of the main portion of the semiconductor device 9 of the ninth embodiment in a y direction, and illustrates a cross section in a direction perpendicular to the cross-sectional view of the main portion in FIG. 38. Here, FIG. 41 is a plan view of the main portion of the semiconductor device 9 of the ninth embodiment. FIG. 38 corresponds to a cross section taken along line X-X in FIG. 41 and illustrates a state in which the second wire M2 is deviated in a -X direction with respect to the first via V1. FIG. 40 corresponds to a cross section taken along line Y-Y in FIG. 41 and illustrates a state in which the second wire M2 is deviated in a -Y direction with respect to the first via V1.

As illustrated in FIGS. 38 to 40, the anchor portion M21 is a conductive member formed in a recess 500b. The anchor portion M21 has a flange portion whose upper portion protrudes from an upper surface 500a of the first insulating film 500 and spreads on the upper surface 500a of the first insulating film 500.

In the anchor portion M21, the shape of the portion protruding from the first insulating film 500 is controlled by a formation condition, and as illustrated in the drawings, an uppermost surface has a flat shape and the flange portion has a wide shape, or the uppermost surface has a curved surface shape and the flange portion has a relatively narrow shape. In the anchor portion M21, when the uppermost portion has a flat shape, the protrusion height on the first insulating film 500 can be reduced, and therefore etching in a manufacturing process described below can be efficiently performed.

Such an anchor portion M21 is connected to the first via V1 in the entire bottom surface of the recess 500b, and is joined to the first via V1 so as to cover the entire upper end surface of the first via V1. As a result, a connection area between the first via V1 and the second wire M2 is ensured, and an increase in connection resistance can be suppressed.

In addition, when there is no positional deviation (misalignment) of the second wire M2 with respect to the first via V1 (see the second portion 9b in FIG. 39), the recess 500b is completely filled with the anchor portion M21.

On the other hand, in a state where positional deviation (misalignment) of the second wire M2 with respect to the first via V1 occurs (see FIGS. 38 and 40), the anchor portion M21 has a joint portion M2a located lower than the upper surface 500a of the first insulating film 500 in the recess 500b. Note that a step [d2] from the upper surface 500a of the first insulating film 500 to the joint portion M2a of the second wire M2, a depth [d1] of the recess 500b, and the like are as described in the first embodiment.

As a conductive material constituting the anchor portion M21 as described above, a material that can serve as an etching stopper in etching of a conductive material constituting the main body layer M20 of the second wire M2 is used. In addition, when the semiconductor device 9 has a wire pitch of 20 nm or less, as the conductive material constituting the anchor portion M21, a material is preferably selected from among the post-Cu materials described in the first embodiment to be used. These materials are desirably made a post-Cu material having an electron mean free path smaller than that of copper (Cu), and examples thereof include metal materials such as ruthenium (Ru), cobalt (Co), molybdenum (Mo), tungsten (W), rhodium (Rh), and iridium (Ir).

### Method for manufacturing semiconductor device of ninth embodiment

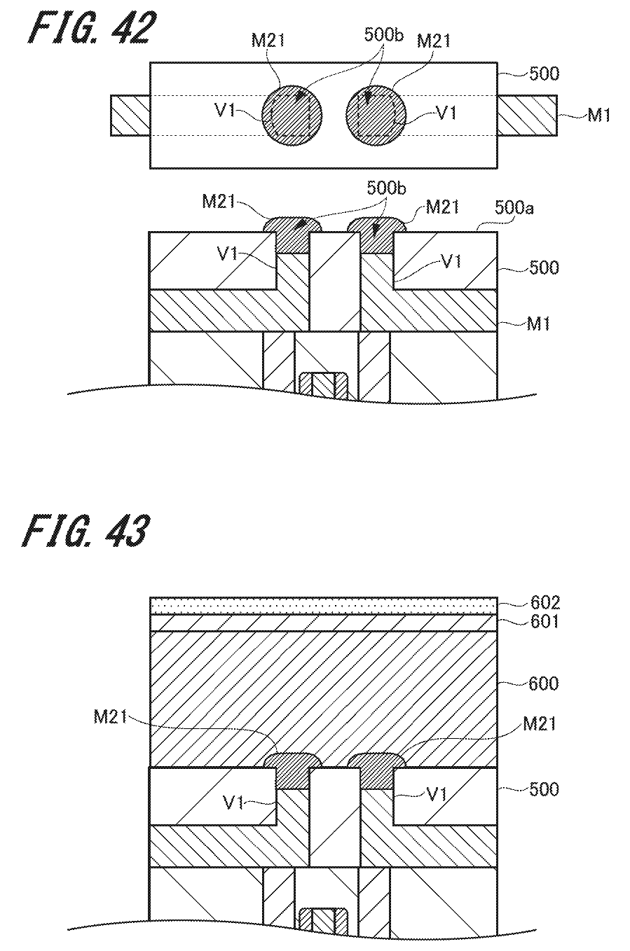

FIGS. 42 to 46 are process diagrams (part 1) to (part 5) illustrating features of a method for manufacturing the semiconductor device of the ninth embodiment. In the method for manufacturing the semiconductor device 9 of the ninth embodiment, first, a step of forming the anchor portion M21 is performed as illustrated in FIG. 42 after the formation of the recess 500b described with reference to FIG. 9 in the method for manufacturing the semiconductor device of the first embodiment and before formation of the second conductive film 600 described with reference to FIG. 10.

The anchor portion M21 illustrated in FIG. 42 is formed by, for example, selective metal growth on the material constituting the first via V1. In this case, for example, a molybdenum (Mo) film is selectively grown on the first via V1 by a selective atomic layer deposition (ALD) method and used as the anchor portion M21. In this selective growth, by growing the metal layer higher than the recess 500b, the metal is isotropically grown in a portion protruding upward from the recess 500b. By such selective metal growth, the anchor portion M21 has a shape having a flange portion spreading on the upper surface 500a of the first insulating film 500. In addition, in this selective metal growth, the shape of a portion protruding from the first insulating film 500 in the anchor portion M21 is controlled by adjusting conditions such as temperature, gas flow rate, pressure, and ALD cycle time as film formation conditions.

Next, as illustrated in FIG. 43, the second conductive film 600, the conductive hard mask layer 601, and the insulating hard mask layer 602 are formed in this order on the first insulating film 500 and the anchor portion M21. These layers are formed in a similar manner to the procedure described with reference to FIG. 10 in the first embodiment. Note that, since the second conductive film 600 is a film constituting the main body layer M20 (see FIG. 38) of the second wire M2, the second conductive film 600 is made of a conductive material different from that of the anchor portion M21.

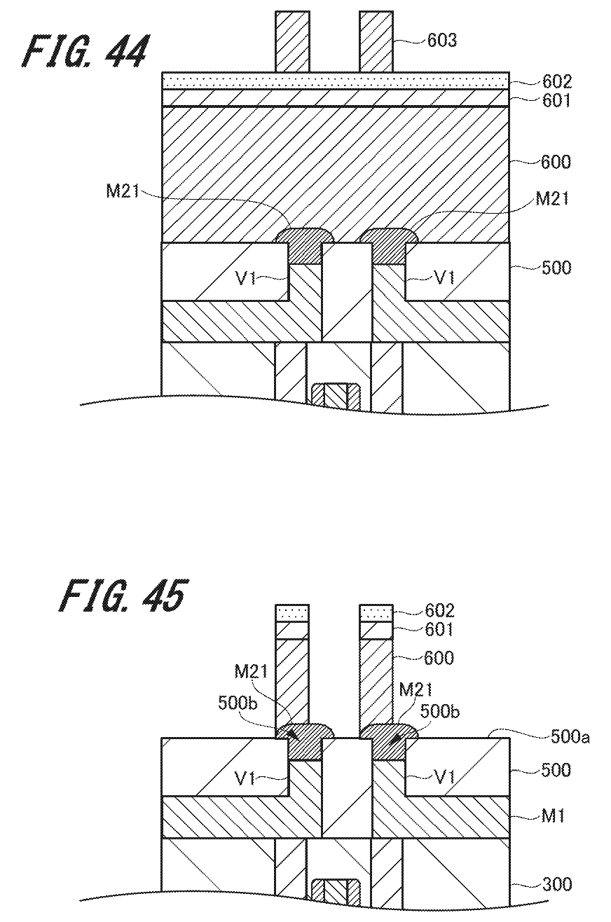

Thereafter, as illustrated in FIG. 44, a resist pattern 603 is formed on the insulating hard mask layer 602. The resist pattern 603 is formed in a similar manner to the procedure described in the first embodiment with reference to FIG. 11.

Next, as illustrated in FIG. 45, using the resist pattern 603 (see FIG. 44) as a mask, the insulating hard mask layer 602, the conductive hard mask layer 601, and the second conductive film 600 are anisotropically dry-etched in this order, and the second conductive film 600 is patterned into the shape of the second wire.

In particular, the second conductive film 600 is etched under an etching condition having a high selectivity with respect to the anchor portion M21. For example, when the anchor portion M21 is made of molybdenum (Mo) and the second conductive film 600 is made of ruthenium (Ru), the second conductive film 600 is selectively and anisotropically etched by a plasma reactive ion etching (RIE) method using an oxygen gas (O₂) as a base etchant. As a result, the etching of the second conductive film 600 is stopped at exposed surfaces of the first insulating film 500 and the anchor portion M21.

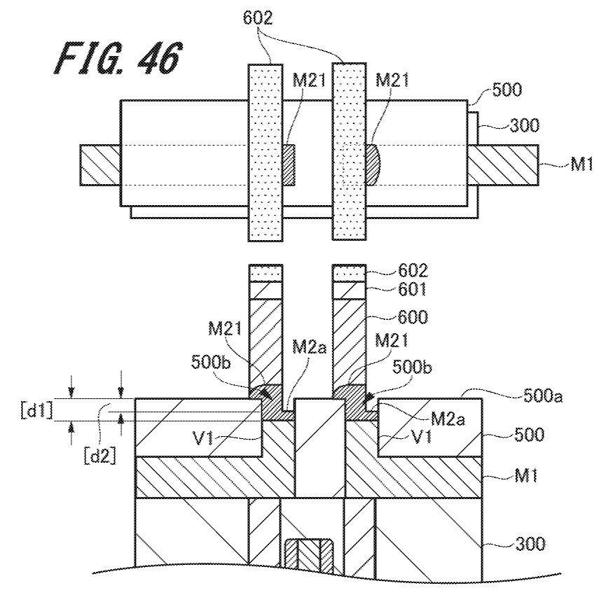

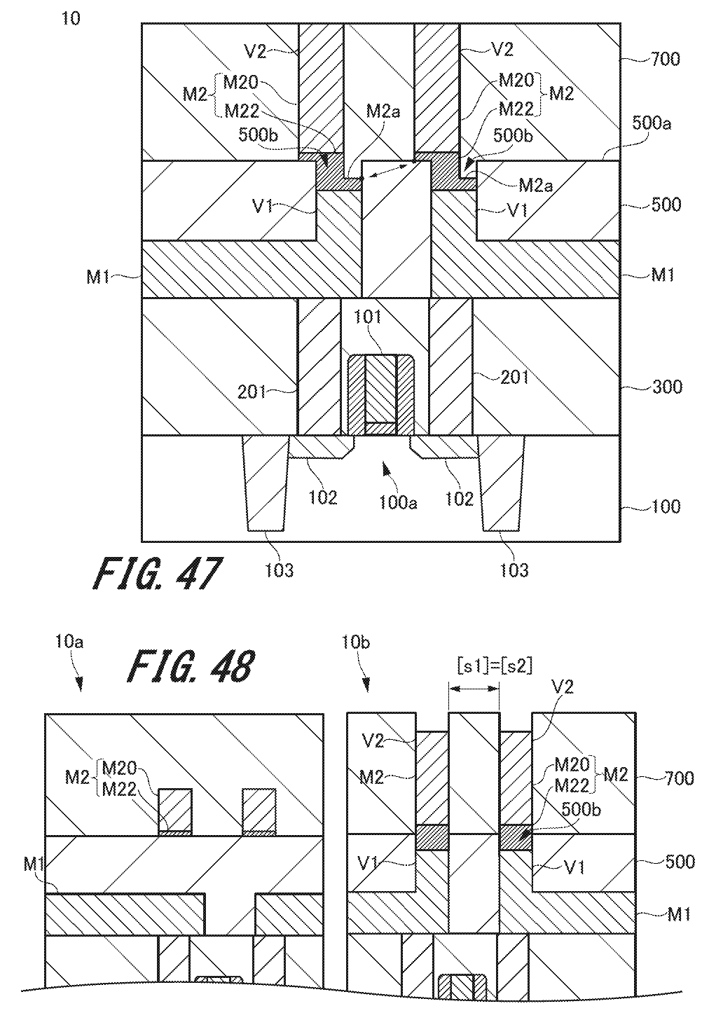

Thereafter, as illustrated in FIG. 46, the etching of the anchor portion M21 is advanced. At this time, the anchor portion M21 is etched such that the anchor portion M21 remains on the entire surface of the first via V1 constituting a bottom surface of the recess 500b in a portion where the recess 500b is exposed from the second conductive film 600 in plan view by misalignment. In addition, the etching of the anchor portion M21 is advanced such that a step [d2] between the upper surface 500a of the first insulating film 500 and the joint portion M2a of the anchor portion M21 is 1/2 or more of a depth [d1] of the recess 500b and 30% or more of a minimum wire interval [s1] as described above. Such etching of the anchor portion M21 is performed by controlling time, thereby leaving the anchor portion M21 on the entire surface in the recess 500b. As an example, in a case where the anchor portion M21 is made of molybdenum (Mo), RIE etching using a chlorine gas (Cl₂) and an oxygen gas (O₂) as base etchants is performed.

Note that the steps described above with reference to FIGS. 45 and 46 may be continuously performed. In this case, for example, using the resist pattern 603 illustrated in FIG. 44 as a mask, the second conductive film 600 and the anchor portion M21 are continuously RIE-etched using a chlorine gas (Cl₂) and an oxygen gas (O₂) as base etchants. In this etching, it is only required to perform time-controlled etching so as to leave the anchor portion M21 in the recess 500b as described above.

After the above step, by performing a procedure similar to the procedure described with reference to FIGS. 13 to 17 in the first embodiment, the semiconductor device 9 described with reference to FIGS. 38 to 41 can be obtained. Note that, after the above step, by repeating the above steps described with reference to FIG. 42, a wire and a via in an upper layer are further formed.

### Effect of ninth embodiment

According to the ninth embodiment described above, since the anchor portion M21 joined to the first via V1 in the second wire M2 is made of a conductive material different from that of the main body layer M20 of the second wire M2, processing accuracy of the second wire M2 can be improved. That is, in the processing of the second wire M2, the second conductive film 600 constituting the main body layer M20 can be etched at a high selectivity with respect to the anchor portion M21. As a result, etching accuracy of the anchor portion M21 can be improved, and the anchor portion M21 can be left with a predetermined film thickness in the recess 500b on the first via V1.

Note that the ninth embodiment can be combined with the second to sixth embodiments. The fourth embodiment in this case also includes a combination with the second embodiment or the third embodiment. In addition, in a case where the fifth embodiment illustrated in FIG. 27 or the sixth embodiment illustrated in FIG. 28 is combined with the ninth embodiment, the second barrier metal layer 607 in FIGS. 27 and 28 is formed on an upper surface of the anchor portion M21.

Furthermore, the ninth embodiment and the combination of the ninth embodiment with another embodiment can also be applied to the seventh embodiment or the eighth embodiment. The ninth embodiment can obtain the effects of these embodiments by being combined with these embodiments.

### Tenth Embodiment

### Configuration of semiconductor device of tenth embodiment

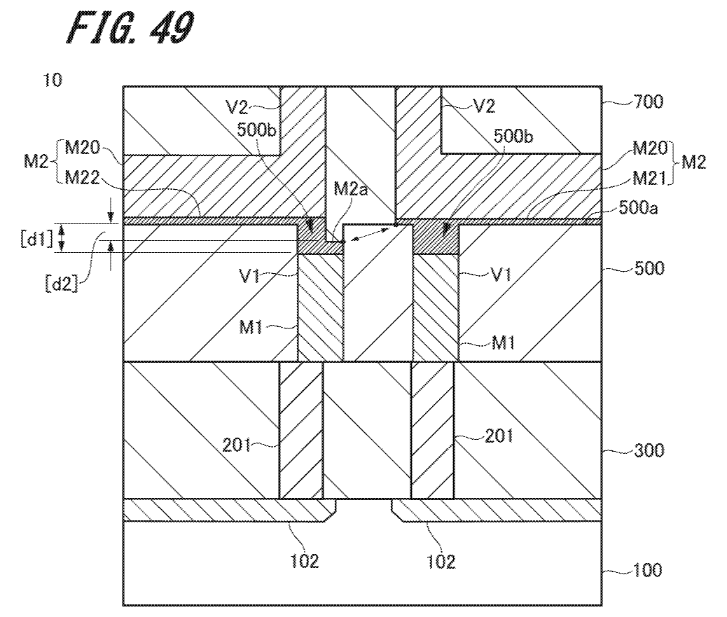

FIG. 47 is a cross-sectional view of a main portion of a semiconductor device 10 of a tenth embodiment, and is a diagram illustrating a portion where misalignment between a first via V1 and a second wire M2 occurs. FIG. 48 is a cross-sectional view of another portion in the semiconductor device 10 of the tenth embodiment, and is a diagram illustrating a cross section of a first portion 10a in which the first via V1 and a second via V2 are not formed and a cross section of a second portion 10b in which misalignment between the first via V1 and the second wire M2 does not occur. FIG. 49 is a cross-sectional view of the main portion of the semiconductor device 10 of the tenth embodiment in a y direction (see FIG. 41), and illustrates a cross section in a direction perpendicular to the cross-sectional view of the main portion in FIG. 47. That is, FIG. 47 corresponds to a cross section taken along line X-X in FIG. 41 and illustrates a state in which the second wire M2 is deviated in a -X direction with respect to the first via V1. FIG. 49 corresponds to a cross section taken along line Y-Y in FIG. 41 and illustrates a state in which the second wire M2 is deviated in a -Y direction with respect to the first via V1.

A difference of the semiconductor device 10 of the tenth embodiment illustrated in FIGS. 47 and 49 from the semiconductor device of the first embodiment is that the second wire M2 has a laminated structure made of different conductive materials, and the other components are similar. That is, the second wire M2 includes a wire lower layer M22 joined to the first via V1 and a main body layer M20 made of a conductive material different from that of the wire lower layer M22.

The wire lower layer M22 is a conductive member formed with a constant film thickness on an upper surface 500a of a first insulating film 500. In addition, the wire lower layer M22 is inserted into a recess 500b of the first insulating film 500, is connected to the first via V1 in the entire bottom surface of the recess 500b, and is joined to the first via V1 so as to cover the entire upper end surface of the first via V1. As a result, a connection area between the first via V1 and the second wire M2 is ensured, and an increase in connection resistance can be suppressed.

In addition, when there is no positional deviation (misalignment) of the second wire M2 with respect to the first via V1 (see the second portion 10b in FIG. 48), the recess 500b is completely filled with the wire lower layer M22.

On the other hand, in a state where positional deviation (misalignment) of the second wire M2 with respect to the first via V1 occurs (see FIGS. 47 and 49), the wire lower layer M22 has a joint portion M2a located lower than the upper surface 500a of the first insulating film 500 in the recess 500b. Note that a step [d2] from the upper surface 500a of the first insulating film 500 to the joint portion M2a of the second wire M2, a depth [d1] of the recess 500b, and the like are as described in the first embodiment.

As a conductive material constituting the wire lower layer M22 as described above, a material that can serve as an etching stopper in etching of a conductive material constituting the main body layer M20 of the second wire M2 is used. In addition, when the semiconductor device 10 has a wire pitch of 20 nm or less, as the conductive material constituting the wire lower layer M22, a material is preferably selected from among the post-Cu materials described in the first embodiment to be used.

### Method for manufacturing semiconductor device of tenth embodiment

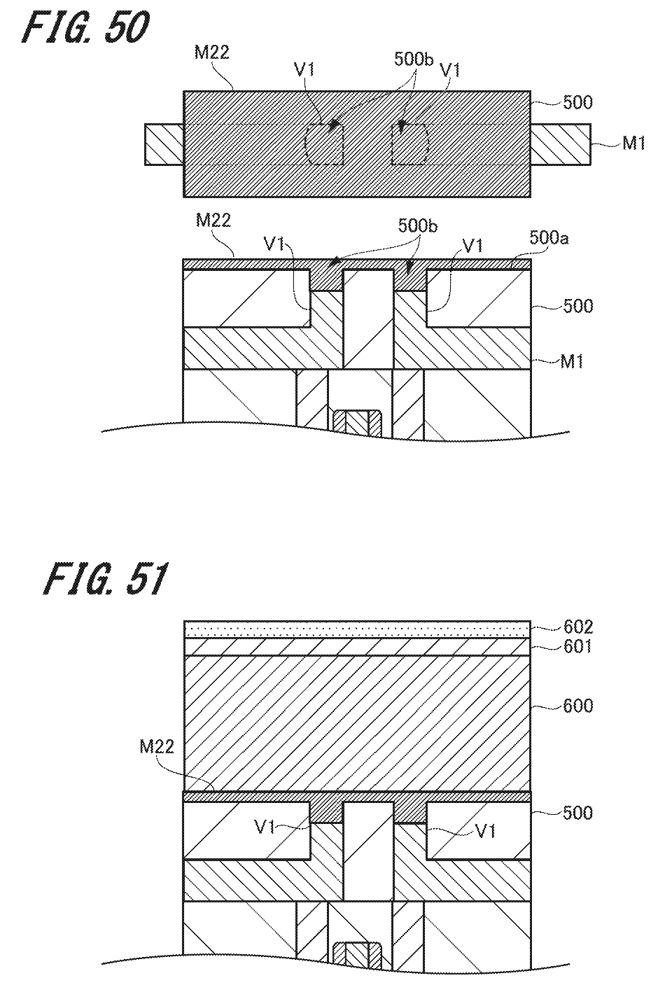

FIGS. 50 to 54 are process diagrams (part 1) to (part 5) illustrating features of a method for manufacturing the semiconductor device of the tenth embodiment. In the method for manufacturing the semiconductor device 10 of the tenth embodiment, first, a step of forming the wire lower layer M22 is performed as illustrated in FIG. 50 after the formation of the recess 500b described with reference to FIG. 9 in the method for manufacturing the semiconductor device of the first embodiment and before formation of the second conductive film 600 described with reference to FIG. 10.

The formation of the wire lower layer M22 illustrated in FIG. 50 is performed in two stages as follows. First, a molybdenum (Mo) film is selectively grown on the first via V1 to a height at which the recess 500b is filled, for example, by a selective ALD method. Thereafter, a molybdenum (Mo) film is formed on the entire surface of the molybdenum (Mo) film selectively grown on the first via V1 and the first insulating film 500 by an ALD method. As a result, the molybdenum (Mo) film selectively grown on the first via V1 and the molybdenum (Mo) film formed on the selectively grown molybdenum (Mo) film constitute the wire lower layer M22. Note that the two-stage film formation for forming the wire lower layer M22 is continuously performed without air-breaking a film formation environment.

Next, as illustrated in FIG. 51, the second conductive film 600, the conductive hard mask layer 601, and the insulating hard mask layer 602 are formed in this order on the wire lower layer M22. These layers are formed in a similar manner to the procedure described with reference to FIG. 10 in the first embodiment. Note that, since the second conductive film 600 is a film constituting the main body layer M20 (see FIGS. 47 to 49) of the second wire M2, the second conductive film 600 is made of a conductive material different from that of the wire lower layer M22.

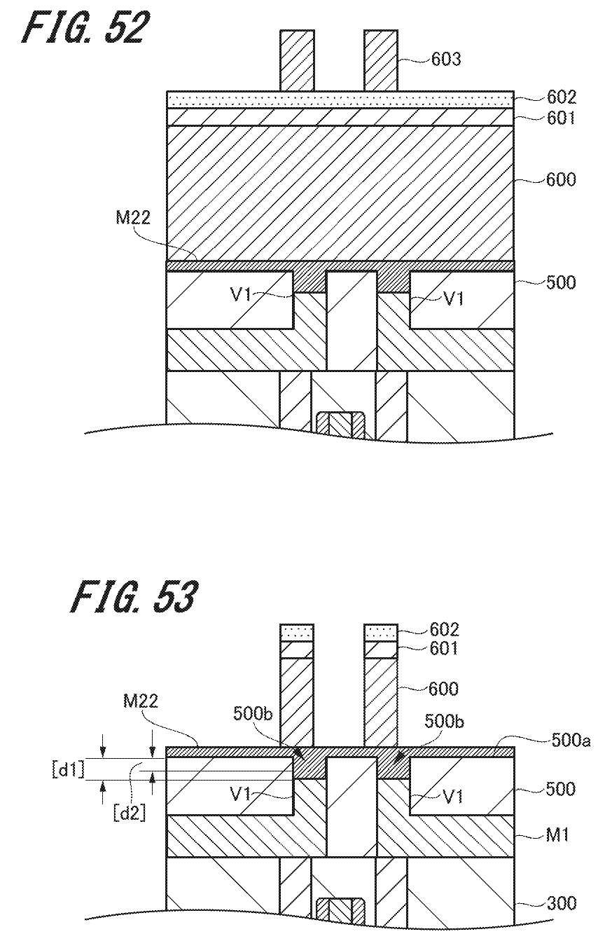

Thereafter, as illustrated in FIG. 52, a resist pattern 603 is formed on the insulating hard mask layer 602. The resist pattern 603 is formed in a similar manner to the procedure described in the first embodiment with reference to FIG. 11.

Next, as illustrated in FIG. 53, using the resist pattern 603 (see FIG. 52) as a mask, the insulating hard mask layer 602, the conductive hard mask layer 601, and the second conductive film 600 are anisotropically dry-etched in this order, and the second conductive film 600 is patterned into the shape of the second wire.

In particular, the second conductive film 600 is etched under an etching condition having a high selectivity with respect to the wire lower layer M22. For example, when the wire lower layer M22 is made of molybdenum (Mo) and the second conductive film 600 is made of ruthenium (Ru), the second conductive film 600 is selectively and anisotropically etched by a plasma reactive ion etching (RIE) method using an oxygen gas (O₂) as a base etchant. As a result, when the etching reaches the wire lower layer M22, the etching of the second conductive film 600 is stopped.

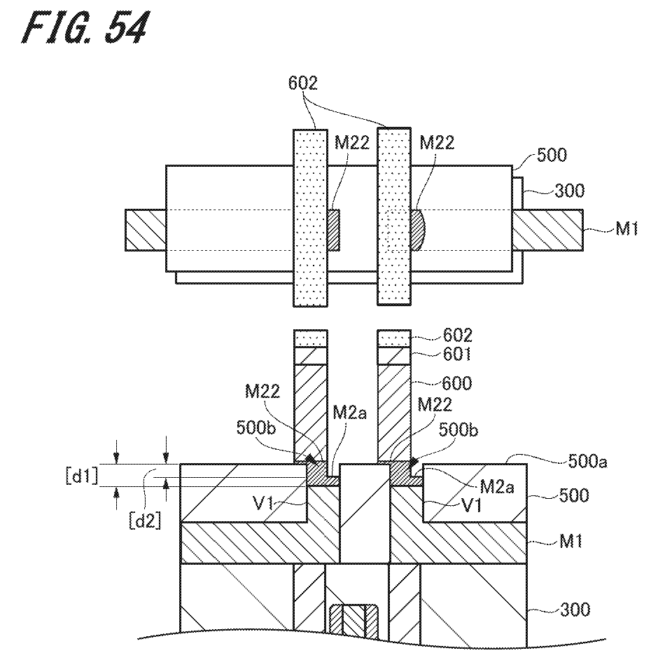

Thereafter, as illustrated in FIG. 54, the etching of the wire lower layer M22 is advanced. At this time, the wire lower layer M22 is etched such that the wire lower layer M22 exposed on the upper surface 500a of the first insulating film 500 is removed. Furthermore, the wire lower layer M22 is etched such that the wire lower layer M22 remains on the entire surface of the first via V1 constituting a bottom surface of the recess 500b in a portion where the recess 500b is exposed from the second conductive film 600 in plan view by misalignment. In addition, the etching of the wire lower layer M22 is advanced such that a step [d2] between the upper surface 500a of the first insulating film 500 and the joint portion M2a of the wire lower layer M22 is 1/2 or more of a depth [d1] of the recess 500b and 30% or more of a minimum wire interval [s1] as described above. Such etching of the wire lower layer M22 is performed by controlling time, thereby leaving the wire lower layer M22 in the recess 500b. As an example, in a case where the wire lower layer M22 is made of molybdenum (Mo), RIE etching using a chlorine gas (Cl₂) and an oxygen gas (O₂) as base etchants is performed.

Note that the steps described above with reference to FIGS. 53 and 54 may be continuously performed. In this case, for example, using the resist pattern 603 illustrated in FIG. 52 as a mask, the second conductive film 600 and the wire lower layer M22 are continuously RIE-etched using a chlorine gas (Cl₂) and an oxygen gas (O₂) as base etchants. In this etching, it is only required to perform time-controlled etching so as to leave the wire lower layer M22 in the recess 500b as described above.

After the above step, by performing a procedure similar to the procedure described with reference to FIGS. 13 to 17 in the first embodiment, the semiconductor device 10 described with reference to FIGS. 47 to 49 can be obtained. Note that, after the above step, by repeating the above steps described with reference to FIG. 50, a wire and a via in an upper layer are further formed.

### Effect of tenth embodiment

According to the tenth embodiment described above, since the wire lower layer M22 joined to the first via V1 in the second wire M2 is made of a conductive material different from that of the main body layer M20 of the second wire M2, processing accuracy of the second wire M2 can be improved. That is, in the processing of the second wire M2, the second conductive film 600 constituting the main body layer M20 can be etched at a high selectivity with respect to the wire lower layer M22. Moreover, at the time of etching the second conductive film 600, the wire lower layer M22 is formed on the entire surface of the first insulating film 500 including the first via V1 (see FIG. 53). Therefore, exposure of the wire lower layer M22 can be easily confirmed by an intensity of each element generated at the time of etching the second conductive film 600, and an end point of the etching of the second conductive film 600 can be detected with high accuracy. As a result, as compared with the ninth embodiment, the etching accuracy of the wire lower layer M22 after etching the second conductive film 600 can be further improved, and the wire lower layer M22 can be left with a predetermined film thickness in the recess 500b on the first via V1.

Note that the tenth embodiment can be combined with the second to sixth embodiments. The fourth embodiment in this case also includes a combination with the second embodiment or the third embodiment. In addition, in a case where the fifth embodiment illustrated in FIG. 27 or the sixth embodiment illustrated in FIG. 28 is combined with the tenth embodiment, the second barrier metal layer 607 in FIGS. 27 and 28 is formed on an upper surface of the wire lower layer M22.

Furthermore, the tenth embodiment and the combination of the tenth embodiment with another embodiment can also be applied to the seventh embodiment or the eighth embodiment. The tenth embodiment can obtain the effects of these embodiments by being combined with these embodiments.

### Reference Signs List

1, 2, 3, 4, 5, 6, 7, 8, 9, 10 Semiconductor device

100 Semiconductor substrate

M1 First wire (lower conductive pattern)

M2 Second wire (upper conductive pattern)

M2a Joint portion

M20 Main body layer

M21 Anchor portion

M22 Wire lower layer

V1, V1' First via (lower conductive pattern)

V1a Upper end surface

V2 Second via (upper conductive pattern)

401 Conductive hard mask layer (sacrificial layer)

407 First barrier metal layer

408 Intermediate barrier metal layer

500 First insulating film

500b, 700b Recess

500c, 700c Airgap

501 Barrier insulating layer

502 First base barrier insulating layer

600 Second conductive film

607 Second barrier metal layer

608 Intermediate barrier metal layer

700 Second insulating film

702 Second base barrier insulating layer

[d1] Depth of recess

[d2] Paragraph

[s1] Minimum wire interval (minimum interval)

1. A semiconductor device comprising:
a plurality of lower conductive patterns formed above a substrate;
a first insulating film formed above the substrate and filling gaps between the plurality of lower conductive patterns;
a plurality of upper conductive patterns formed on the first insulating film and joined to the plurality of lower conductive patterns; and
a second insulating film formed on the first insulating film and filling gaps between the plurality of upper conductive patterns, wherein
a recess having an upper end surface of the lower conductive pattern as a bottom surface is formed from an upper surface of the first insulating film,
in a portion where the lower conductive pattern and the upper conductive pattern are positionally deviated, the upper conductive pattern has a joint portion located lower than an upper surface of the first insulating film in the recess, and
the upper conductive pattern is joined to the lower conductive pattern so as to cover the entire upper end surface of the lower conductive pattern.

2. The semiconductor device according to claim 1, wherein
a step between the upper surface of the first insulating film and an upper surface of the joint portion in the upper conductive pattern is 30% or more of a minimum interval between the lower conductive patterns and between the upper conductive patterns.

3. The semiconductor device according to claim 2, wherein
a depth of the recess is 1/3 or more of the minimum interval.

4. The semiconductor device according to claim 1, wherein
a barrier insulating layer is formed on the upper surface of the first insulating film and a sidewall of the recess.

5. The semiconductor device according to claim 1, wherein
a first base barrier insulating layer is formed under the first insulating film and on a sidewall of the first insulating film, and
a second base barrier insulating layer is formed under the second insulating film and on a sidewall of the second insulating film.

6. The semiconductor device according to claim 1, wherein
the first insulating film has an airgap between the lower conductive patterns, and
the second insulating film has an airgap between the upper conductive patterns.

7. The semiconductor device according to claim 1, wherein
barrier metal layers are formed below the lower conductive pattern and below the upper conductive pattern, respectively.

8. The semiconductor device according to claim 7, wherein
each of the lower conductive pattern and the upper conductive pattern includes a wire and a via above the wire, and
an intermediate barrier metal layer is formed between the wire and the via.

9. The semiconductor device according to claim 1, wherein
the upper conductive pattern includes an anchor portion formed in the recess, and a main body layer formed above the anchor portion and on the upper surface of the first insulating film, and
the anchor portion and the main body layer are made of different conductive materials.

10. The semiconductor device according to claim 1, wherein
the upper conductive pattern includes a wire lower layer formed in the recess and on the upper surface of the first insulating film, and a main body layer formed on an upper surface of the wire lower layer, and
the wire lower layer and the main body layer are made of different conductive materials.

11. A method for manufacturing a semiconductor device, the method comprising:
a step of forming a plurality of lower conductive patterns above a substrate;
a step of forming a first insulating film filling gaps between the plurality of lower conductive patterns above the substrate;
a step of forming a recess having an upper end surface of the lower conductive pattern as a bottom surface from an upper surface of the first insulating film by removing a recess above the lower conductive pattern exposed to the upper surface of the first insulating film;
a step of forming a plurality of upper conductive patterns joined to the plurality of lower conductive patterns by patterning a conductive film formed on the lower conductive pattern and the first insulating film; and
a step of forming a second insulating film filling gaps between the plurality of upper conductive patterns on the first insulating film, wherein
in the step of forming the upper conductive patterns,
after the conductive film is patterned by anisotropic etching until the first insulating film is exposed,
in a portion where the lower conductive pattern and the upper conductive pattern are positionally deviated, the conductive film is further anisotropically etched so as to leave the conductive film on an entire upper end surface of the lower conductive pattern in the recess.

12. The method for manufacturing a semiconductor device according to claim 11, wherein
an uppermost portion of the lower conductive pattern is formed of a sacrificial layer, and
when the recess above the lower conductive pattern is removed, the recess is formed at a depth corresponding to a film thickness of the sacrificial layer by selectively removing the sacrificial layer.

13. The method for manufacturing a semiconductor device according to claim 11, wherein
in the step of forming the upper conductive pattern,
an anchor portion of the conductive film is formed in the recess by selective growth for the lower conductive pattern, and then a main body layer of the conductive film made of a conductive material different from that of the anchor portion is formed above the anchor portion and on the first insulating film, and
the main body layer is etched by etching at a high selectivity with respect to the anchor portion, and then the anchor portion is etched to form the upper conductive pattern.

14. The method for manufacturing a semiconductor device according to claim 11, wherein
in the step of forming the upper conductive pattern,
a wire lower layer of the conductive film is formed in the recess and on an upper surface of the first insulating film, and then a main body layer of the conductive film made of a conductive material different from that of the wire lower layer is formed, and
the main body layer is etched by etching at a high selectivity with respect to the wire lower layer, and then the wire lower layer is etched to form the upper conductive pattern.
